(19) United States
(12) Patent Application Publication
(10) Pub. No.: US 2023/0369367 A1
(43) Pub. Date: Nov. 16, 2023

(54) PASSIVATION FOR A DEEP TRENCH ISOLATION STRUCTURE IN A PIXEL SENSOR

(71) Applicant: Taiwan Semiconductor Manufacturing Company, Ltd., Hsinchu (TW)

(72) Inventors: Yu-Hung CHENG, Tainan City (TW); Yu-Siang FANG, Tainan (TW); Yu-Yao HSIA, Tainan (TW); Ching I LI, Tainan (TW)

(21) Appl. No.: 17/663,108

(22) Filed: May 12, 2022

(51) Int. Cl. H01L 27/146

(52) U.S. Cl. CPC H01L 27/1463; H01L 27/14645; H01L 27/14621; H01L 27/14627; H01L 27/14689; H01L 27/14698

(57) ABSTRACT

A boron layer may be formed as a passivation layer in a recess in which a deep trench isolation structure (DTI) structure is to be formed. The boron layer results in formation of a boron-silicon interface between the DTI structure and a photodiode of a pixel sensor included in a pixel array. The boron-silicon interface functions as a diode junction, which resists penetration of photons into the DTI structure. This reduces and/or minimizes photon transmission through the DTI structure, which reduces and/or minimizes optical crosstalk between pixel sensors of the pixel array.

### BACKGROUND

A complementary metal oxide semiconductor (CMOS) image sensor may include a plurality of pixel sensors. A pixel sensor of the CMOS image sensor may include a transfer transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example pixel array described herein.

FIGS. 3A, 3B, and 4A-4D are diagrams of examples of a pixel sensor described herein.

FIGS. 5A-5Q are diagrams of an example implementation described herein.

FIG. 6 is a diagram of example components of one or more devices described herein.

FIGS. 7 and 8 are flowcharts of example processes associated with forming a pixel sensor described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Optical crosstalk can occur between adjacent pixel regions in a pixel array. Optical crosstalk is a pixel array performance issue, whereby incident light passes through a pixel sensor at a non-orthogonal angle and is at least partially absorbed by a photodiode of an adjacent pixel sensor. A pixel array may include deep trench isolation (DTI) structures between adjacent pixel sensors to reduce optical crosstalk and/or to increase photon absorption in a pixel sensor. However, in some cases, photons may still pass through (or diffuse through) a DTI structure, which may result in optical crosstalk between adjacent pixel sensors. Optical crosstalk in a pixel array of an image sensor can degrade the spatial resolution of the image sensor, can reduce overall sensitivity of the image sensor, can cause color mixing between pixel sensors of the image sensor, can increase dark current levels of the image sensor, can reduce optical responsivity of the image sensor, can reduce white pixel performance, and/or can lead to image noise after color correction.

Some implementations described herein provide passivation techniques and layers for a DTI structure that are configured to reduce optical crosstalk for pixel sensors in a pixel array. As described herein, a boron (B) layer may be formed as a passivation layer in a recess in which a DTI structure is to be formed. The recess may then be filled with an oxide material over the boron layer (and/or one or more intervening layers) to form the DTI structure.

The boron layer described herein results in formation of a boron-silicon interface between the DTI structure and a photodiode of a pixel sensor included in the pixel array. The boron atoms in the boron layer form strong chemical bonds with the silicon atoms in the silicon of a substrate in which the photodiode is formed, which reduces the quantity of silicon dangling bonds that would otherwise act as recombination centers. The boron-silicon interface functions as a diode junction having unique heterojunction properties as a result of the electronegativity difference between the boron atoms of the boron layer and the silicon atoms of the substrate. Thus, the boron-silicon interface resists penetration of photons into the DTI structure. This reduces and/or minimizes photon transmission through the DTI structure, which reduces and/or minimizes optical crosstalk between pixel sensors of the pixel array. Accordingly, the passivation techniques and layers described herein may increase spatial resolution of an image sensor that includes the pixel array, may increase overall sensitivity of the image sensor, may reduce color mixing between the pixel sensors of the image sensor, may reduce dark current levels of the image sensor, may increase optical responsivity of the image sensor, and/or may provide reduced image noise after color correction, among other examples.

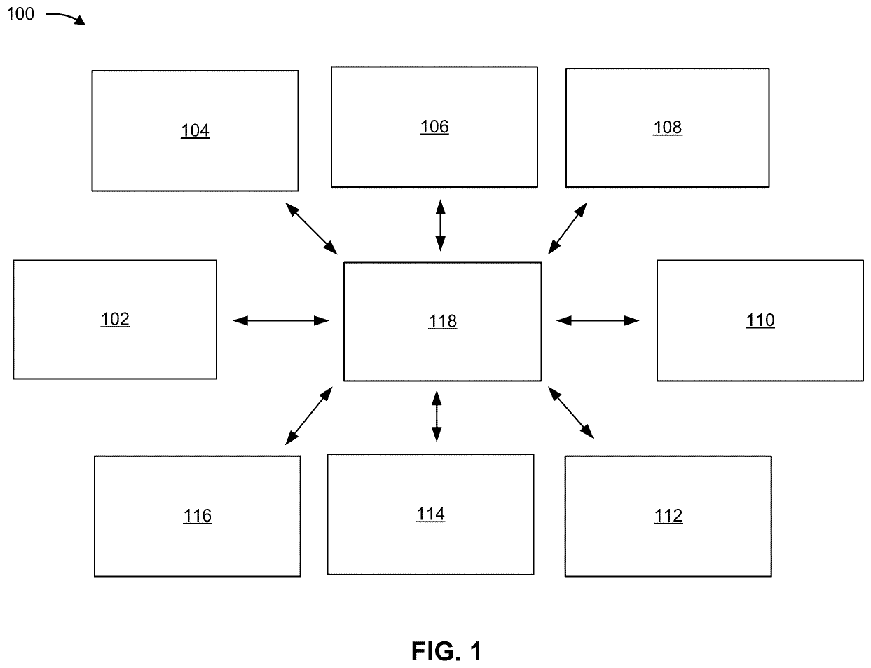

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, an annealing tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The annealing tool 116 is a semiconductor processing tool that includes a semiconductor processing chamber and one or more devices capable of heating a semiconductor substrate or semiconductor device. For example, the annealing tool 116 may include a rapid thermal annealing (RTA) tool or another type of annealing tool that is capable of heating a semiconductor substrate to cause a reaction between two or more materials or gasses, to cause a material to decompose. As another example, the annealing tool 116 may be configured to heat (e.g., raise or elevate the temperature of) a structure or a layer (or portions thereof) to re-flow the structure or the layer, or to crystallize the structure or the layer, to remove defects such as voids or seams. As another example, the annealing tool 116 may be configured to heat (e.g., raise or elevate the temperature of) a layer (or portions thereof) to enable bonding of two or more semiconductor devices.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may form, in a substrate, a photodiode for a pixel sensor of a pixel array; may form, in the substrate, a drain region for the pixel sensor; may form, in the substrate, a trench adjacent to the photodiode and the drain region; may form an amorphous boron layer on sidewalls of the trench and on a bottom surface of the trench; may form an amorphous silicon layer on the amorphous boron layer; and/or may fill the trench with an oxide material over the amorphous silicon layer to form a DTI structure, among other examples. As another example, one or more of the semiconductor processing tools 102-116 and/or the wafer/die transport tool 118 may form, in a substrate, a photodiode for a pixel sensor of a pixel array; may form, in the substrate, a drain region for the pixel sensor; may form, in the substrate, a trench adjacent to the photodiode and the drain region; may form a boron layer on sidewalls of the trench and on a bottom surface of the trench; may perform an annealing operation to anneal the boron layer after forming the boron layer; may form a silicon layer on the boron layer after performing the annealing operation; and/or may fill the trench with an oxide material over the silicon layer to form a DTI structure, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

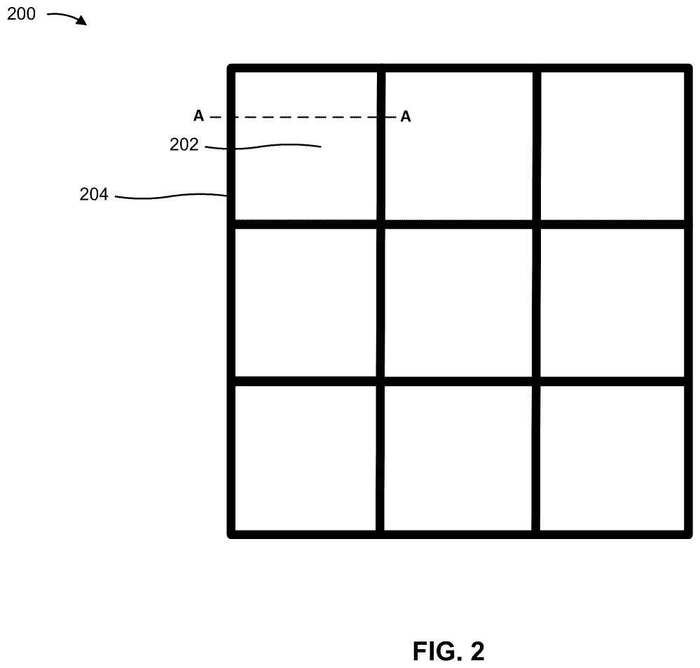

FIG. 2 is a diagram of an example pixel array 200. FIG. 2 illustrates a top-down view of the pixel array 200. In some implementations, the pixel array 200 may be included in an image sensor. The image sensor may include a complementary metal oxide semiconductor (CMOS) image sensor, a backside illuminated (BSI) CMOS image sensor, a front side illuminated (FSI) CMOS image sensor, or another type of image sensor. As shown in FIG. 2, the pixel array 200 may include a plurality of pixel sensors 202. As further shown in FIG. 2, the pixel sensors 202 may be arranged in a grid. In some implementations, the pixel sensors 202 are square-shaped (as shown in the example in FIG. 2). In some implementations, the pixel sensors 202 include other shapes such as rectangle shapes, circle shapes, octagon shapes, diamond shapes, and/or other shapes.

The pixel sensors 202 may be configured to sense and/or accumulate incident light (e.g., light directed toward the pixel array 200). For example, a pixel sensor 202 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

In some implementations, the size of the pixel sensors 202 (e.g., the width or the diameter) of the pixel sensors 202 is approximately 1 micron. In some implementations, the size of the pixel sensors 202 (e.g., the width or the diameter) of the pixel sensors 202 is less than approximately 1 micron. In these examples, the pixel sensors 202 may be referred to as sub-micron pixel sensors. Sub-micron pixel sensors may decrease the pixel sensor pitch (e.g., the distance between adjacent pixel sensors) in the pixel array 200, which may enable increased pixel sensor density in the pixel array 200 (which can increase the performance of the pixel array 200).

The pixel sensors 202 may be electrically and optically isolated by a DTI structure 204 included in the pixel array 200. The DTI structure 204 may include a plurality of interconnected trenches that are filled with a dielectric material such as an oxide. The trenches of the DTI structure 204 may be included around the perimeters of the pixel sensors 202 such that the DTI structure 204 surrounds the pixel sensors 202 (and the photodiodes and drain regions included therein), as shown in FIG. 2. Moreover, the trenches of the DTI structure 204 may extend into a substrate in which the pixel sensors 202 are formed to surround the photodiodes and other structures of the pixel sensors 202 in the substrate. As indicated above, the pixel array 200 may be included in a BSI CMOS image sensor. In these examples, the DTI structure 204 may include a backside DTI (BDTI or BSDTI) structure with a high aspect ratio that is formed from the backside of the pixel array 200.

The pixel array 200 may be electrically connected to a back-end-of-line (BEOL) metallization stack (not shown) of the image sensor. The BEOL metallization stack may electrically connect the pixel array 200 to control circuitry that may be used to measure the accumulation of incident light in the pixel sensors 202 and convert the measurements to an electrical signal. For a BSI CMOS image sensor, the transistor layer may be located between the BEOL metallization stack layers and a lens layer. For a FSI CMOS image sensor, the BEOL metallization stack layers may be located between the transistor layer and the lens layer.

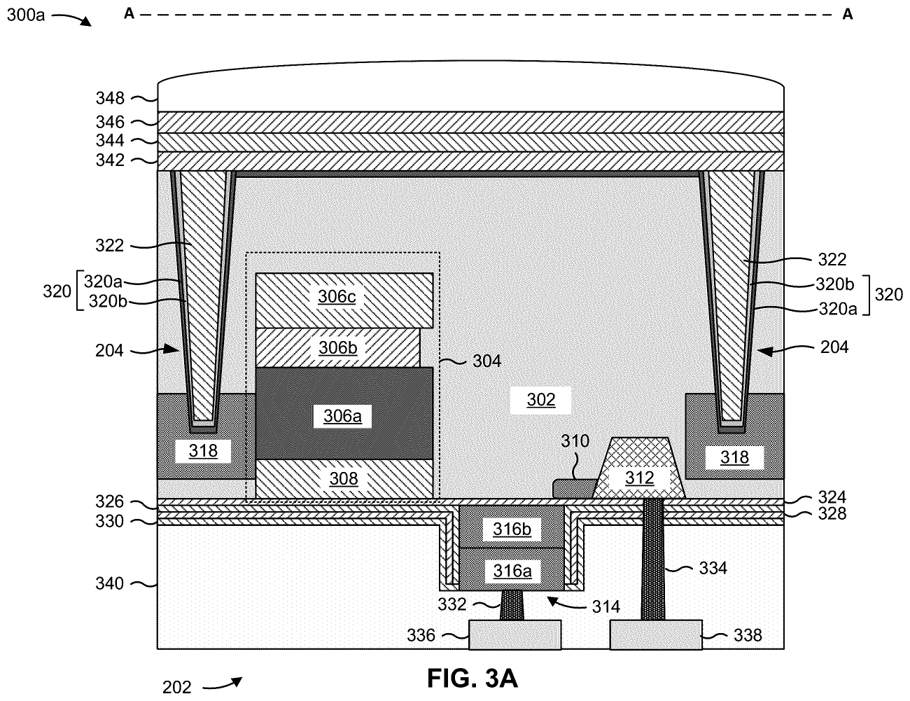

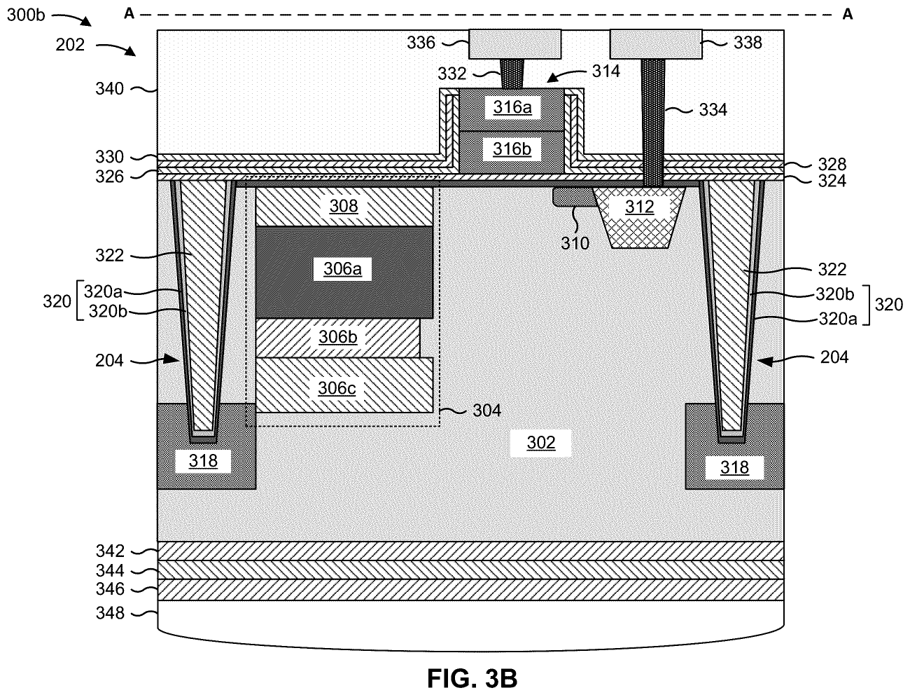

FIG. 2 further illustrates a reference cross-section A-A that is used in one or more figures described herein, such as one or more of FIGS. 3-5O. Cross-section A-A is in a plane across a pixel sensor 202 of the pixel array 200. Subsequent figures refer to this reference cross-section for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

FIGS. 3A and 3B are diagrams of example configurations s of a pixel sensor 202 described herein. In particular, FIGS. 3A and 3B illustrate the example configurations in cross-section views of the pixel sensor 202 along the cross-section A-A of the pixel array 200 in FIG. 2. In some implementations, the pixel sensor 202 may be included in the pixel array 200. In some implementations, the pixel sensor 202 may be included in an image sensor. The image sensor may be a CMOS image sensor, a BSI CMOS image sensor, or another type of image sensor.

FIG. 3A includes an example configuration 300a of a back side DTI CMOS image sensor (BS-DTI-CIS) configuration for a pixel sensor 202. As shown in FIG. 3A, the pixel sensor 202 may include a substrate 302. The substrate 302 may include a semiconductor die substrate, a semiconductor wafer, a stacked semiconductor wafer, or another type of substrate in which semiconductor pixels may be formed. In some implementations, the substrate 302 is formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 302 is formed of a doped material (e.g., a p-doped material or an n-doped material) such as a doped silicon.

The pixel sensor 202 may include a photodiode 304 that is included in the substrate 302. The photodiode 304 may include a plurality of regions that are doped with various types of ions to form a p-n junction or a PIN junction (e.g., a junction between a p-type portion, an intrinsic (or undoped) type portion, and an n-type portion). For example, the substrate 302 may be doped with an n-type dopant to form one or more n-type regions 306 of the photodiode 304, and the substrate 302 may be doped with a p-type dopant to form a p-type region 308 of the photodiode 304. The photodiode 304 may be configured to absorb photons of incident light. The absorption of photons causes the photodiode 304 to accumulate a charge (referred to as a photocurrent) due to the photoelectric effect. Photons may bombard the photodiode 304, which causes emission of electrons in the photodiode 304.

The regions included in the photodiode 304 may be stacked and/or vertically arranged. For example, the p-type region 308 may be included over the one or more n-type regions 306. The p-type region 308 may provide noise isolation for the one or more n-type regions 306 and may facilitate photocurrent generation in the photodiode 304. In some implementations, the p-type region 308 (and thus, the photodiode 304) is spaced away (e.g., downward) from a top surface of the substrate 302 to provide noise isolation and/or light-leakage isolation from one or more upper layers of the pixel sensor 202. The gap between the top surface of the substrate 302 and the p-type region 308 may decrease charging of the pixel sensor 202, may decrease the likelihood of plasma damage to the photodiode 304, and/or may reduce the dark current of the pixel sensor 202 and/or the white pixel performance of the pixel sensor 202, among other examples.

The one or more n-type regions 306 may include an n-type region 306a, an n-type region 306b, and an n-type region 306c. The n-type region 306b may be located over and/or on the n-type region 306c, and the n-type region 306a may be located over and/or on the n-type region 306b. The n-type region 306b and the n-type region 306c may be referred to as deep n-type regions or deep n-wells and may extend the n-type region 306 of the photodiode 304. This may provide an increased area for photon absorption in the photodiode 304. Moreover, at least a subset of the one or more n-type regions 306 may have different doping concentrations. For example, the n-type region 306a may include a greater n-type dopant concentration relative to the n-type region 306b and the n-type region 306c, and the n-type region 306b may include a greater n-type dopant concentration relative to the n-type region 306c. As a result, an n-type dopant gradient is formed, which may increase the migration of electrons upward in the photodiode 304.

The pixel sensor 202 may include a drain extension region 310 and a drain region 312 coupled and/or electrically connected to the drain extension region 310. The drain extension region 310 may be adjacent to the drain region 312. The drain region 312 may include a highly-doped n-type region (e.g., an n⁺ doped region). The drain extension region 310 may include lightly-doped n-type region(s) that facilitate the transfer of photocurrent from the n-type region 306a to the drain region 312. In some implementations, the drain extension region 310 is spaced away (e.g., downward) from a frontside surface of the substrate 302 to provide noise isolation and/or light-leakage isolation from one or more upper layers of the pixel sensor 202. The gap between the frontside surface of the substrate 302 and the drain extension region 310 may increase noise isolation for the drain extension region 310, may decrease random noise and/or random telegraph noise in the pixel sensor 202, may decrease the likelihood of plasma damage to the drain extension region 310, and/or may reduce the dark current of the pixel sensor 202 and/or the white pixel performance of the pixel sensor 202, among other examples.

The pixel sensor 202 may include a transfer gate 314 to control the transfer of photocurrent between the photodiode 304 and the drain region 312. The transfer gate 314 may be energized (e.g., by applying a voltage or a current to the transfer gate 314) to cause a conductive channel to form between the photodiode 304 and the drain extension region 310. The conductive channel may be removed or closed by de-energizing the transfer gate 314, which blocks and/or prevents the flow of photocurrent between the photodiode 304 and the drain region 312.

The transfer gate 314 may include a gate electrode stack that includes an n-doped upper transfer gate electrode region 316a and a lower transfer gate electrode region 316b. The lower transfer gate electrode region 316b may be included over a portion of the frontside surface of the substrate 302, and the n-doped upper transfer gate electrode region 316a may be located over and/or on the lower transfer gate electrode region 316b. The n-doped upper transfer gate electrode region 318a may include a layer of n⁺ doped polysilicon. The lower transfer gate electrode region 316b may include a layer of polysilicon.

The pixel sensor 202 may include a plurality of regions to provide electrical isolation and/or optical isolation between the pixel sensor 202 and adjacent pixel sensors. The pixel sensor 202 may include a deep p-well region (DPW) 318 adjacent to, and at least partially surrounding, the photodiode 304. In some implementations, the pixel sensor 202 further includes a cell p-well region (CPW) above the deep p-well region 318. The deep p-well region 318 (and the cell p-well region, if included) may include a circle or ring shape in a top-down view in the substrate 302. The deep p-well region 318 (and the cell p-well region, if included) may each include a p⁺ doped silicon material or another p⁺ doped material.

The DTI structure 204 may be included in the substrate 302 adjacent to the photodiode 304 and the drain region 312. Moreover, the DTI structure 204 may be included above and/or partially in the deep p-well region 318. In some implementations, the DTI structure 204 may be included in a cell p-well region. The DTI structure 204 may include one or more trenches that extend downward into the substrate 302 (e.g., from the backside of the substrate 302), and that are that are adjacent the photodiode 304, the drain extension region 310, and the drain region 312. In a top-down view of the pixel sensor 202, the DTI structure 204 may surround the photodiode 304, the drain extension region 310, and the drain region 312. In other words, the photodiode 304, the drain extension region 310, and the drain region 312 may be included within a perimeter of the DTI structure 204 of the pixel sensor 202. The DTI structure 204 may provide optical isolation between the pixel sensor 202 and one or more adjacent pixel sensors to reduce the amount of optical crosstalk between the pixel sensor 202 and the one or more adjacent pixel sensors. In particular, the DTI structure 204 may absorb, refract, and/or reflect photons of incident light, which may reduce the amount of incident light that travels through a pixel sensor 202 into an adjacent pixel sensor and is absorbed by the adjacent pixel sensor.

The DTI structure 204 may include one or more layers 320 between the substrate 302 of the pixel sensor 202 and an oxide layer 322 of the DTI structure 204. The one or more layers 320 may include a passivation layer 320a and a capping layer 320b, among other examples. The passivation layer 320a may be included between the substrate 302 (e.g., the silicon substrate) of the pixel sensor 202 and the capping layer 320b. The capping layer 320b may be included between the passivation layer 320a and the oxide layer 322.

The passivation layer 320a may include a boron (B) material, an amorphous boron (a-B) material, and/or another material. The capping layer 320b may include a silicon (Si) material, an amorphous silicon (a-Si) material, and/or another material. The passivation layer 320a may be included to further decrease optical crosstalk by providing a boron-silicon interface between the passivation layer 320a and the substrate 302. The boron-silicon interface resists, reduces, and/or minimizes penetration and/or diffusion of photons into the oxide layer 322. The capping layer 320b may be included to protect the passivation layer 320a from damage during one or more semiconductor processing operations for forming the pixel sensor 202. The passivation layer 320a (e.g., an amorphous boron layer) may be included on the back side of the pixel sensor 202 (e.g., on the back side of the substrate), as shown in the example in FIG. 3A.

The oxide layer 322 may function to reflect incident light toward the photodiode 304 to increase the quantum efficiency of the pixel sensor 202 and to reduce optical crosstalk between the pixel sensor 202 and one or more adjacent pixel sensors. In some implementations, the oxide layer 322 includes an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another type of dielectric material is used in place of the oxide layer 322.

A gate dielectric layer 324 may be included above and/or over the frontside surface of the substrate 302. The lower transfer gate electrode region 316b may be included over and/or on the gate dielectric layer 324. The gate dielectric layer 324 may include a dielectric material such as tetraethyl orthosilicate (TEOS) or another type of dielectric material. A sidewall oxide layer 326 may be included over and/or the gate dielectric layer 324 on the frontside surface of the substrate 302. The sidewall oxide layer 326 may also be included on sidewalls of the n-doped upper transfer gate electrode region 316a and/or on sidewalls of the lower transfer gate electrode region 316b. The sidewall oxide layer 326 may include an oxide such as silicon oxide (SiOₓ) or another type of oxide material. A remote plasma oxide (RPO) layer 328 may be included over and/or on the sidewall oxide layer 326 over the frontside surface of the substrate 302. The remote plasma oxide layer 328 may also be included over the sidewall oxide layer 326 on the sidewalls of the n-doped upper transfer gate electrode region 316a and/or over the sidewall oxide layer 326 on the sidewalls of the lower transfer gate electrode region 316b. A contact etch stop layer (CESL) 330 may be included over and/or on the remote plasma oxide layer 328 over the frontside surface of the substrate 302. The contact etch stop layer 330 may also be included over the remote plasma oxide layer 328 on the sidewalls of the n-doped upper transfer gate electrode region 316a and/or over remote plasma oxide layer 328 on the sidewalls of the lower transfer gate electrode region 316b.

The transfer gate 314 and the drain region 312 may be electrically connected by interconnects 332 and 334, respectively, with respective metallization layers 336 and 338 above the substrate 302. The interconnects 332 and 334, and the metallization layers 336 and 338, may be included in one or more dielectric layers 340. The interconnect 332 may be electrically connected with the transfer gate 314 by the n-doped upper transfer gate electrode region 316a. In some implementations, the dielectric layer(s) 340 surround and/or encapsulate the interconnects 332 and 334, as well as the metallization layers 336 and 338. The dielectric layer(s) 340 may include an inter-metal dielectric (IMD) layer formed of an oxide material such as a silicon oxide (SiOₓ) (e.g., silicon dioxide (SiO₂)), a silicon nitride (SiNₓ), a silicon carbide (SiCₓ), a titanium nitride (TiNₓ), a tantalum nitride (TaNₓ), a hafnium oxide (HfOₓ), a tantalum oxide (TaOₓ), or an aluminum oxide (AlOₓ), or another type of dielectric material. The interconnects 332 and 334, as well as the metallization layers 336 and 338, may include one or more conductive materials, such as tungsten (W), cobalt (Co), ruthenium (Ru), copper (Cu), and/or another type of conductive material.

As further shown in FIG. 3A, the pixel sensor 202 may include one or more layers on the back side or a bottom side of the substrate 302. On the substrate 302 (e.g., on the bottom of the substrate 302), a p⁺ ion layer 342 may be included to increase photon-electron conversion. An antireflective coating (ARC) layer 344 may be included above and/or on the p⁺ ion layer 342. The ARC 344 may include a suitable material for reducing a reflection of incident light projected toward the photodiode 304. For example, the ARC 344 may include nitrogen-containing material.

A color filter layer 346 may be included above and/or on the ARC 344. In some implementations, the color filter layer 346 includes a visible light color filter configured to filter a particular wavelength or a particular wavelength range of visible light (e.g., red light, blue light, or green light). In some implementations, the color filter layer 346 includes a near infrared (NIR) filter (e.g., an NIR bandpass filter) configured to permit wavelengths associated with NIR light to pass through the color filter layer 346 and to block other wavelengths of light. In some implementations, the color filter layer 346 includes an NIR cut filter configured to block NIR light from passing through the color filter layer 346. In some implementations, the color filter layer 346 is omitted from the pixel sensor 202 to permit all wavelengths of light to pass through to the photodiode 304. In these examples, the pixel sensor 202 may be configured as a white pixel sensor.

A micro-lens layer 348 may be included above and/or on the color filter layer 346. The micro-lens layer 348 may include a micro-lens for the pixel sensor 202 configured to focus incident light toward the photodiode 304 and/or to reduce optical crosstalk between the pixel sensor 202 and one or more adjacent pixel sensors.

In operation of the pixel sensor 202, a photocurrent generated by photons of incident light absorbed in the photodiode 304 may originate in the one or more n-type regions 306a-306c. A current (or voltage) may be applied to the transfer gate 314 from the metallization layer 336 through an interconnect 332, the n-doped upper transfer gate electrode region 316a, and the lower transfer gate electrode region 316b. The current (or voltage) may energize the transfer gate 314, which causes an electric field to form a conductive channel in the substrate 302 between the n-type region 306a and the drain extension region 310. The photocurrent may traverse along the conductive channel from the n-type region 306a to the drain extension region 310. The photocurrent may traverse from the drain extension region 310 to the drain region 312. The photocurrent may be measured through the interconnect 334 at the metallization layer 338.

FIG. 3B includes an example configuration 300b of a front side DTI CMOS image sensor (FS-DTI-CIS) configuration for a pixel sensor 202. In the example configuration 300b, the DTI structure 320 is formed in the substrate 302 from a front side or top side of the substrate 302. In the example configuration 300b, the p-type region 308 may be included over the one or more n-type regions 306. The n-type region 306b may be included over and/or on the n-type region 306c, the n-type region 306a may be included over and/or on the n-type region 306b. The p-type region 308 may be included over and/or on the n-type region 306a.

The frontside DTI CIS configuration may include the passivation layer 320a (and, in some cases, the capping layer 320b). The passivation layer 320a (which may include a boron layer) may be included between the substrate 302 and the DTI oxide layer 322 of the DTI structure 204, may be included between the deep p-well region 318 and the oxide layer 322 of the DTI structure 204, and/or may be included on the substrate 302 between the substrate and the gate dielectric layer 324, among other examples. The front end of line (FEOL) thermal budget may be carefully managed for the pixel sensor 202, when the FS-DTI-CIS configuration is used, to prevent from Boron diffusion from the passivation layer 320a into other areas and/or structures of the pixel sensor 202. In some cases, the passivation layer 320a may be removed from the surface of the substrate 302 prior to formation of the of gate dielectric layer 324 to prevent boron diffusion into the substrate 302 due to thermal issues. A sulfuric acid-hydrogen peroxide solution (SPM) clean or standard clean (e.g., SC1, SC2) may be used to remove the passivation layer 320a from the surface of the substrate 302.

As further shown in FIG. 3B, the pixel sensor 202 may include one or more layers on the front side or a bottom side of the substrate 302. On the substrate 302 (e.g., on the top of the substrate 302), a p⁺ ion layer 342 may be included to increase photon-electron conversion. An antireflective coating (ARC) layer 344 may be included above and/or on the p⁺ ion layer 342. A color filter layer 346 may be included above and/or on the ARC 344. A micro-lens layer 348 may be included above and/or on the color filter layer 346.

As indicated above, FIGS. 3A and 3B are provided as examples. Other examples may differ from what is described with regard to FIGS. 3A and 3B.

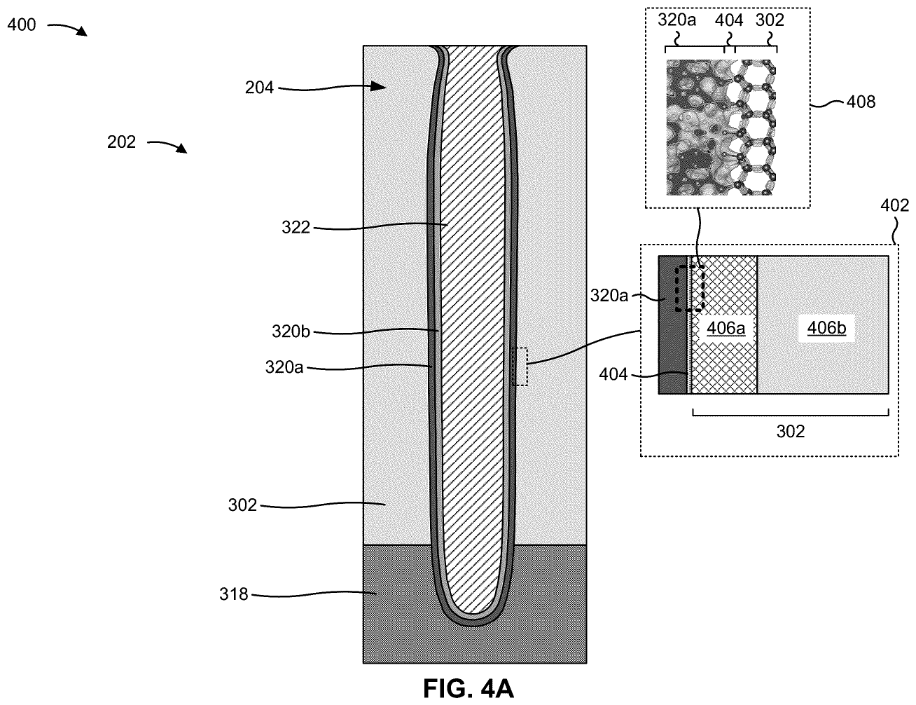

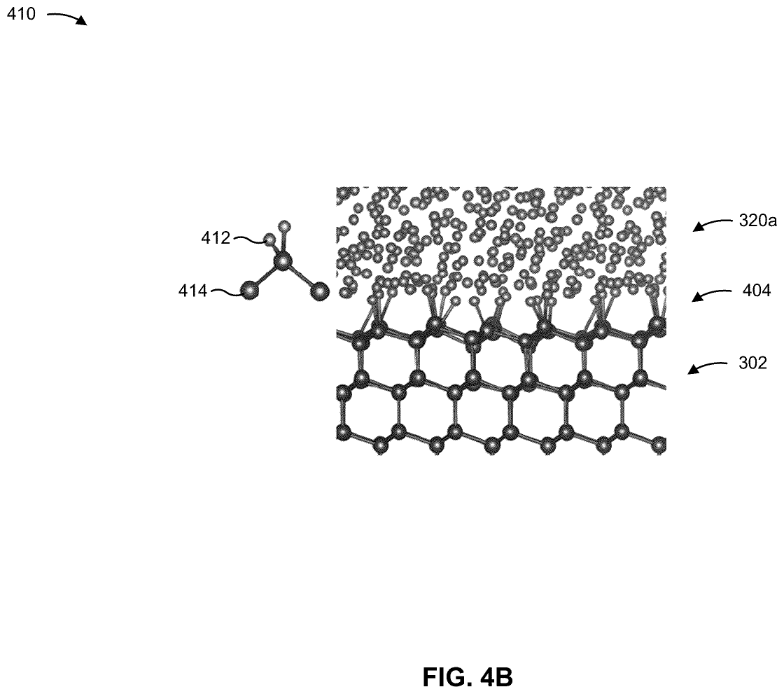

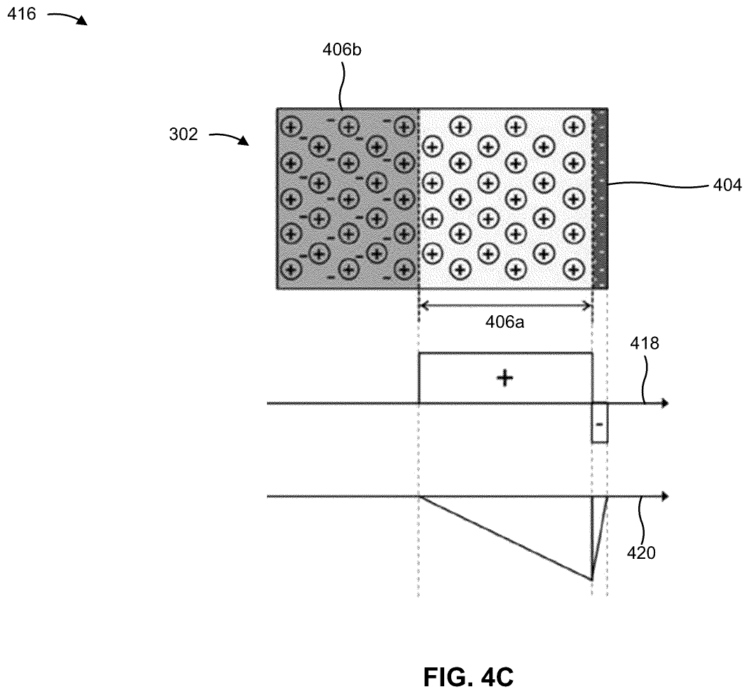

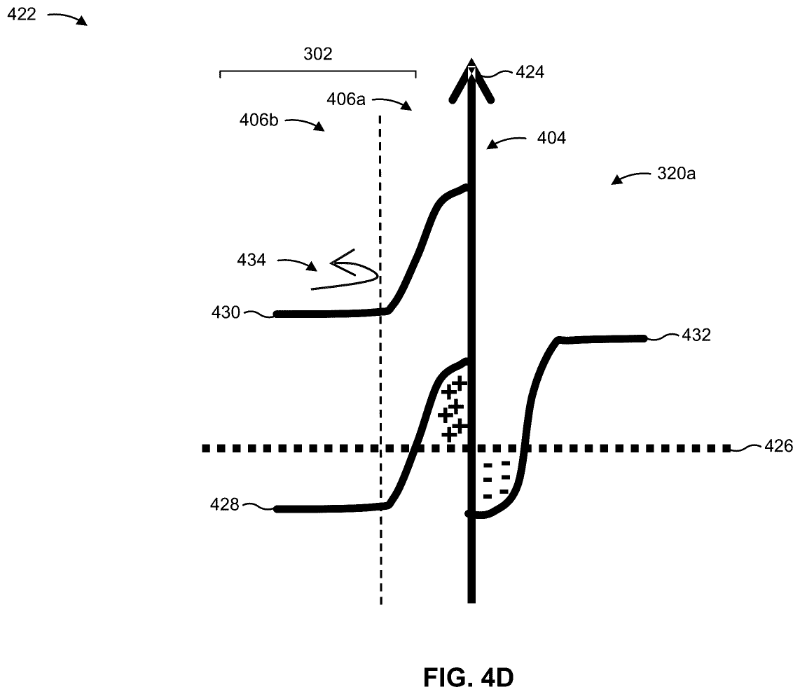

FIGS. 4A-4D are diagrams of examples a pixel sensor 202 described herein. In particular, FIGS. 4A-4D illustrate examples of the pixel sensor 202 described in connection with FIGS. 3A and/or 3B.

FIG. 4A illustrates an example 400 of the DTI structure 204 of the pixel sensor 202. As shown in FIG. 4A, the DTI structure 204 includes an elongated structure that extends into the substrate 302 and into a portion of the deep p-well region 318. The DTI structure 204 may include a rounded bottom portion in the deep p-well region 318. The DTI structure 204 may also exhibit some necking (e.g., a reduction in width or critical dimension) at a top of the DTI structure 204.

As shown in a detailed view 402 in FIG. 4A, an interface 404 may be included between the passivation layer 320a and the substrate 302. The interface 404 may include a boron-silicon interface where the boron of the passivation layer 320a and the silicon of the substrate 302 are bonded. The difference in electronegativity between the boron and the silicon at the interface 404 results in formation of a depletion region 406a in the substrate 302 adjacent to the interface 404 and between the interface 404 and a non-depletion region 406b of the substrate 302. For example, the electronegativity of boron may be approximately 2.04, whereas the electronegativity of silicon may be approximately 1.90. As shown in a detailed view 408 of the interface 404 in FIG. 4A, the boron atoms of the passivation layer 320a and the silicon atoms of the substrate 302 are bonded directly at the interface 404.

FIG. 4B illustrates an example 410 of the bonding between boron atoms 412 of the passivation layer 320a and silicon atoms 414 of the substrate 302. As shown in FIG. 4B, boron atoms 412 of the passivation layer 320a and silicon atoms 414 of the substrate 302 are bonded directly at the interface 404. At the interface 404, the boron of the passivation layer 320a and the silicon of the substrate 302 form strong chemical bonds, which reduces the quantity of silicon dangling bonds in the silicon of the substrate 302. Moreover, and as described herein, the boron of the passivation layer 320a is deposited in a manner that reduces, minimizes, and/or prevents formation of boron silicide (BₓSi_{y}) at the interface 404.

FIG. 4C illustrates an example 416 of the depletion region 406a. As shown in FIG. 4C, the depletion region 406a is depleted of electrons. The depletion of electrons results from a charge transfer in the substrate 302 adjacent to the interface 404, where negatively charged electrons are transferred from the depletion region 406a to the non-depletion region 406b of the substrate 302. Accordingly, a charge density 418 in the depletion region 406a includes a fixed charge density having a positive charge, which results in the depletion region 406a being configured to resist photon penetration in the DTI structure 204. The charge transfer occurs because the electrons in the substrate 302 are repelled by the boron atoms 412 of the passivation layer 320a at the interface 404, which has a charge density 418 that is negative. The high negative charge density 418 results in a charge transfer in the substrate 302 that facilitates the formation of the depletion region 406a in the substrate 302 adjacent to the interface 404. The charge transfer may be approximately 0.75 electrons per silicon (e/Si) atom or another charge transfer value.

The high positive charge density 418 in the depletion region 406a and the high negative charge density 418 at the interface 404 result in formation of an electric field having an electric field intensity 420 that increases from a first side of the depletion region 406a adjacent to the non-depletion region 406b of the substrate 302 to a second side of the depletion region 406a adjacent to the interface 404. The electric field intensity 420 may be greatest at the interface 404 and may decrease from a first side of the interface 404 adjacent to the depletion region 406a to a second side adjacent to the passivation layer 320a.

FIG. 4D illustrates an example 422 of one or more diode junction properties at or near the interface 404. As shown in FIG. 4D, an energy band diagram illustrates energy 424 (E in electron volts (ev)) and the Fermi level 426 (E_{F}) along the non-depletion region 406b, the depletion region 406a, the interface 404, and the passivation layer 320a. As further shown in FIG. 4D, the energy level of an energy band 428 (e.g., a valence band (E_{V})) and the energy level of an energy band 430 (e.g., conduction band (E_{C})) increases in the depletion region 406a from the non-depletion region 406b to the interface 404 due to band bending near the interface 404. The band bending of the energy band 428 in the depletion region 406a results in the energy band 428 being greater than the Fermi level 426 near the interface 404, which results in an accumulation of positive charge in the depletion region 406a.

In the passivation layer 320a, the energy level of an energy band 432 increases from the interface 404 into the passivation layer 320a away from the interface 404 due to band bending near the interface 404. The band bending of the energy band 432 results in the energy band 432 being less than the Fermi level 426 near the interface 404 in the passivation layer 320a, which results in an accumulation of negative charge in the passivation layer 320a near the interface 404.

The accumulation of positive charge in the depletion region 406a and the accumulation of negative charge in the passivation layer 320a at the interface 404 result in a fixed charge at the interface 404. The fixed charge at the interface 404 facilitates resistance against photon penetration into the DTI structure 204, as shown by reference number 434 in FIG. 4D, which increases the optical isolation provided by the DTI structure 204.

As indicated above, FIGS. 4A-4D are provided as examples. Other examples may differ from what is described with regard to FIGS. 4A-4D.

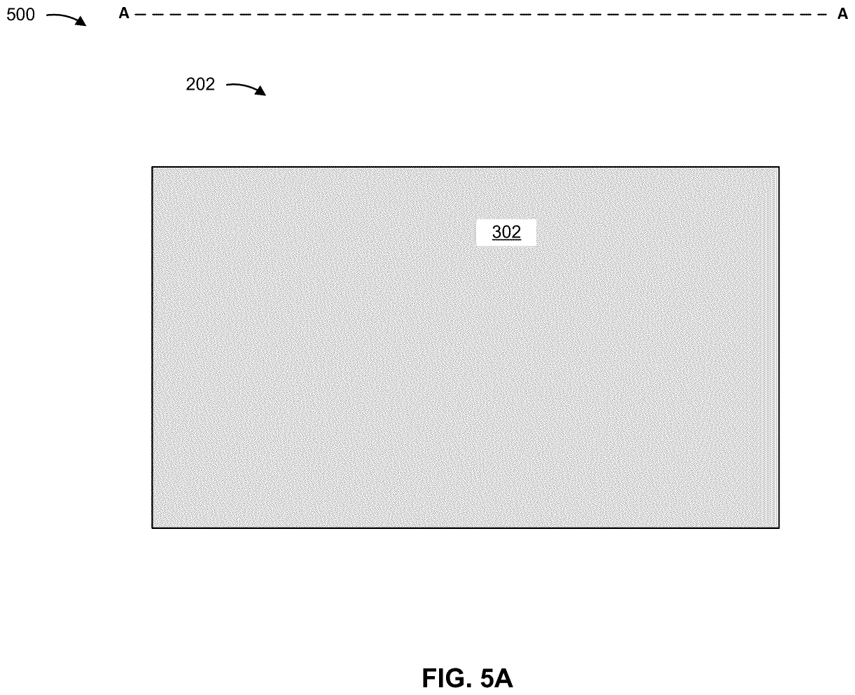

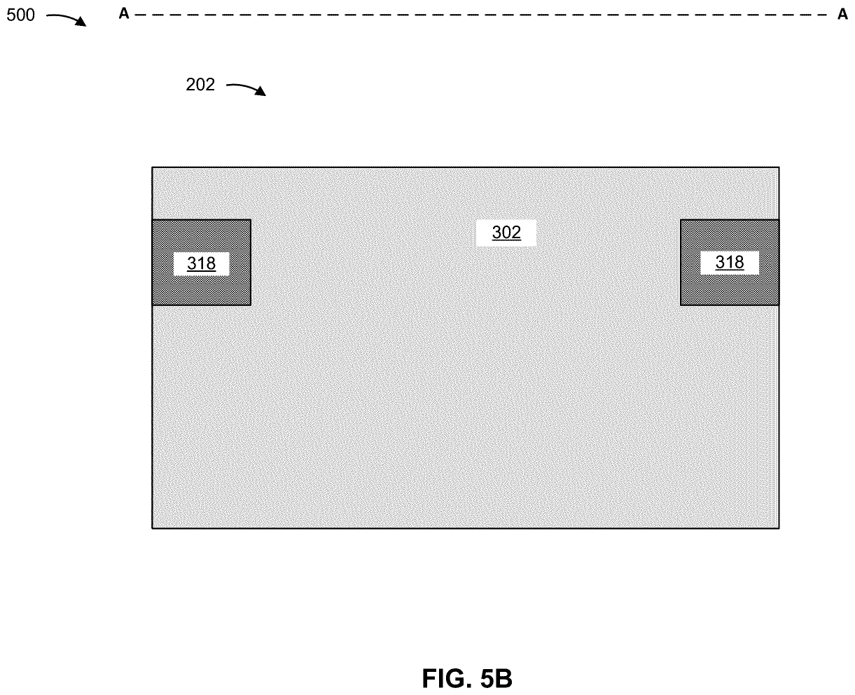

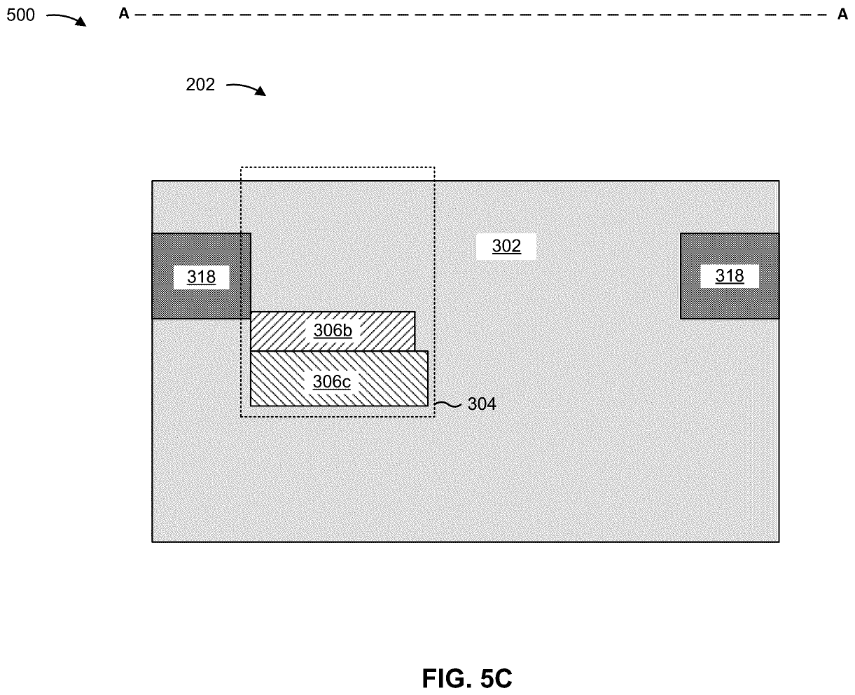

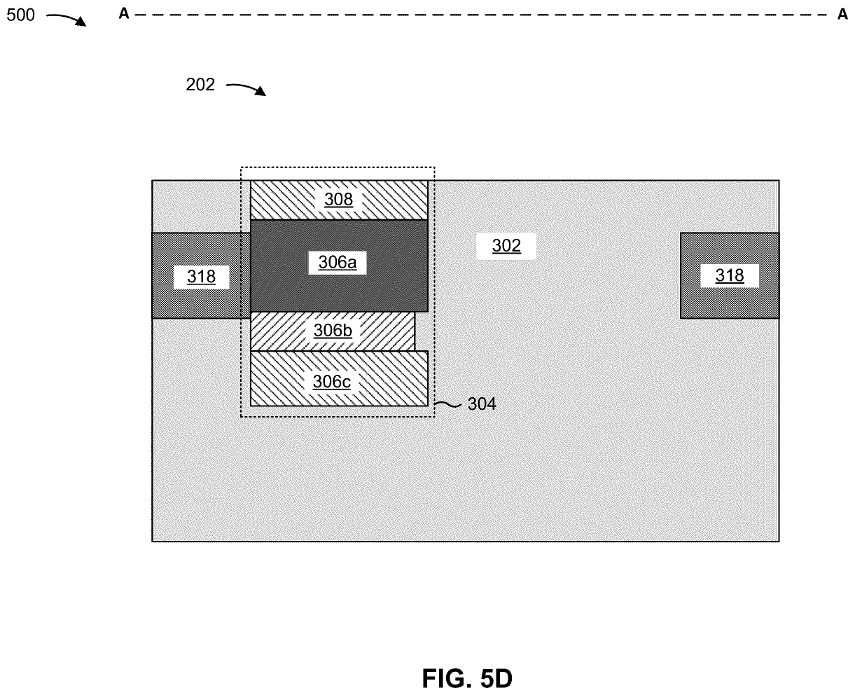

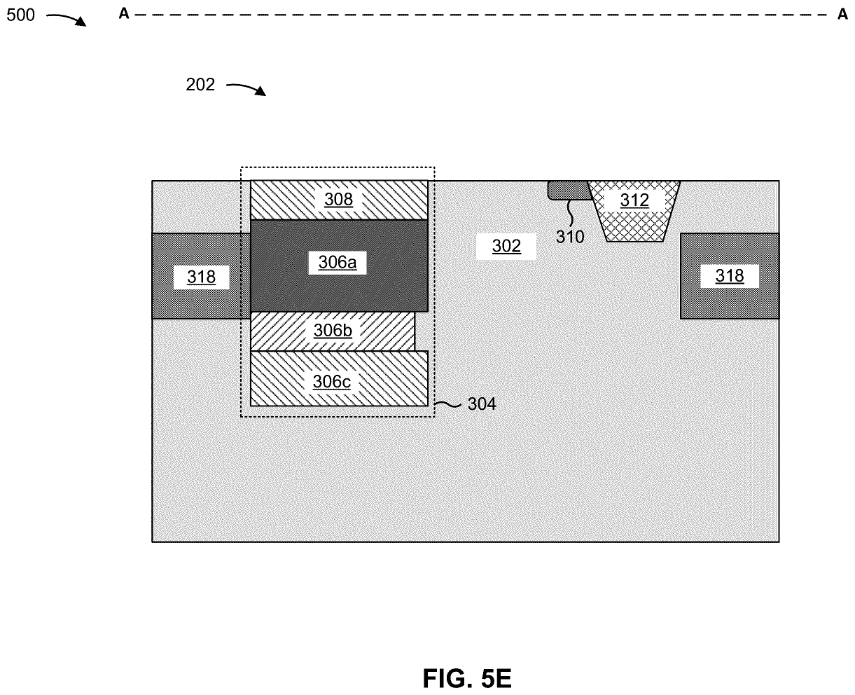

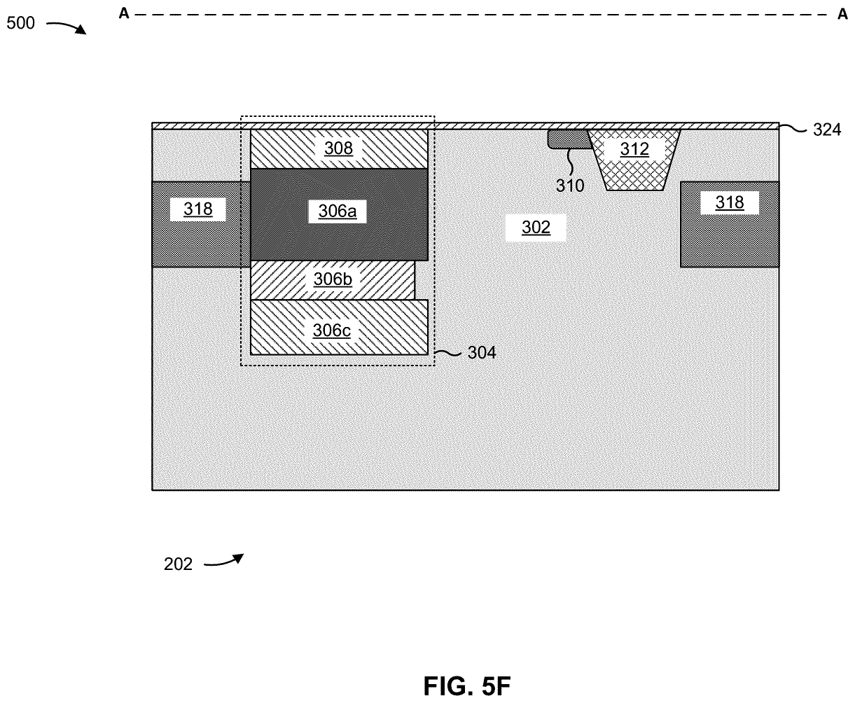

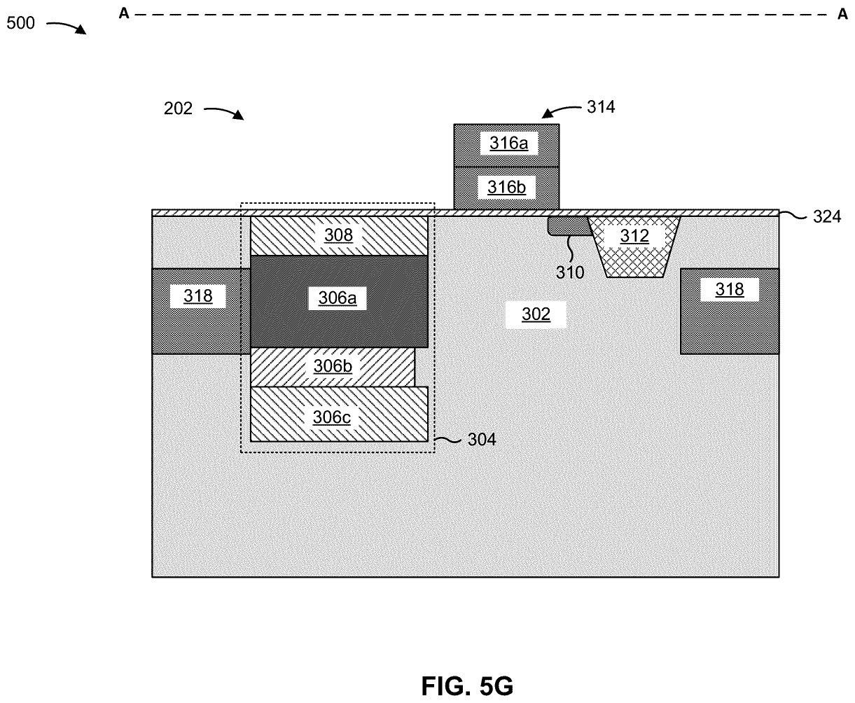

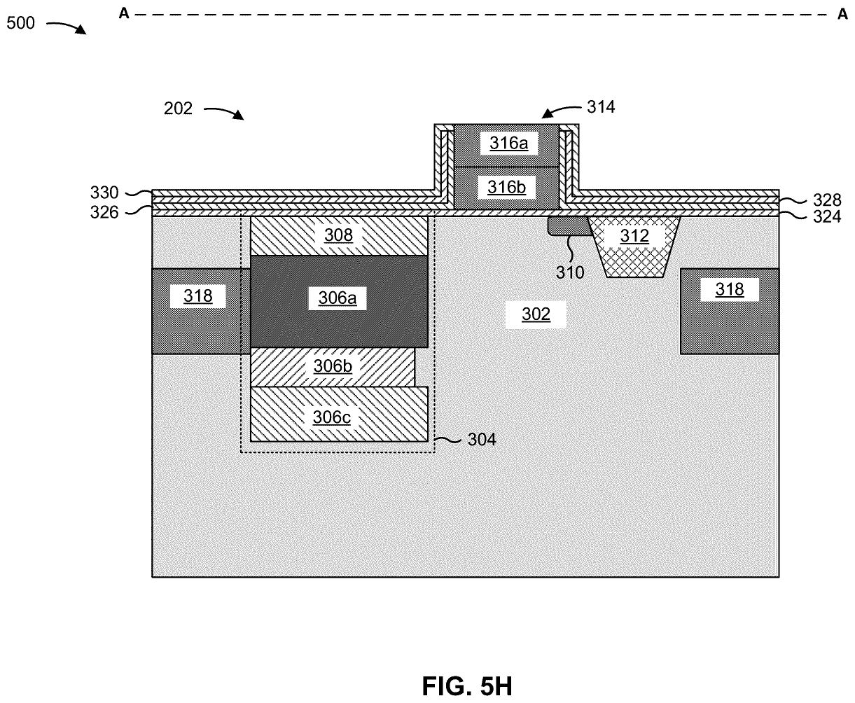

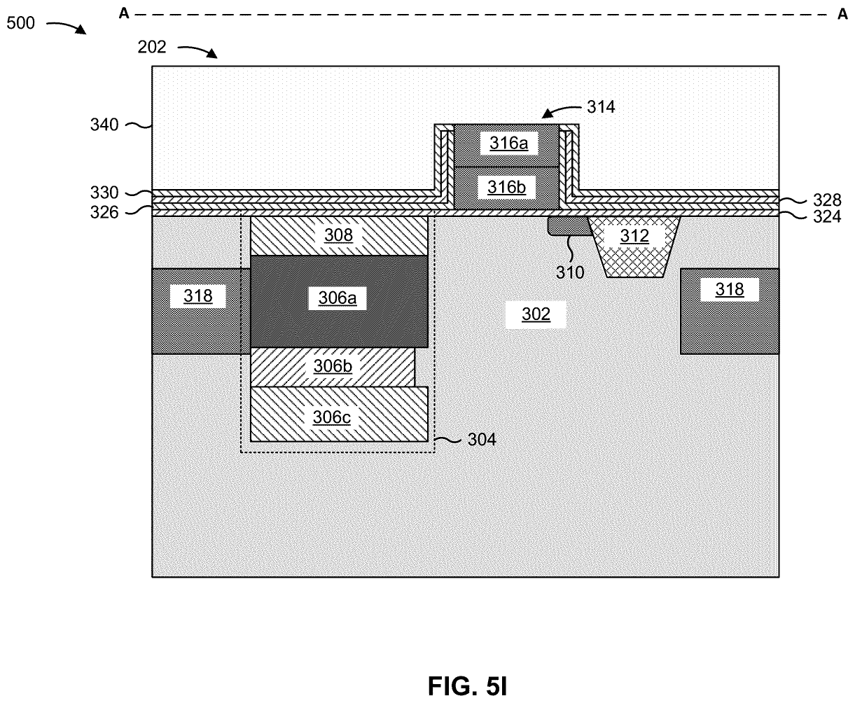

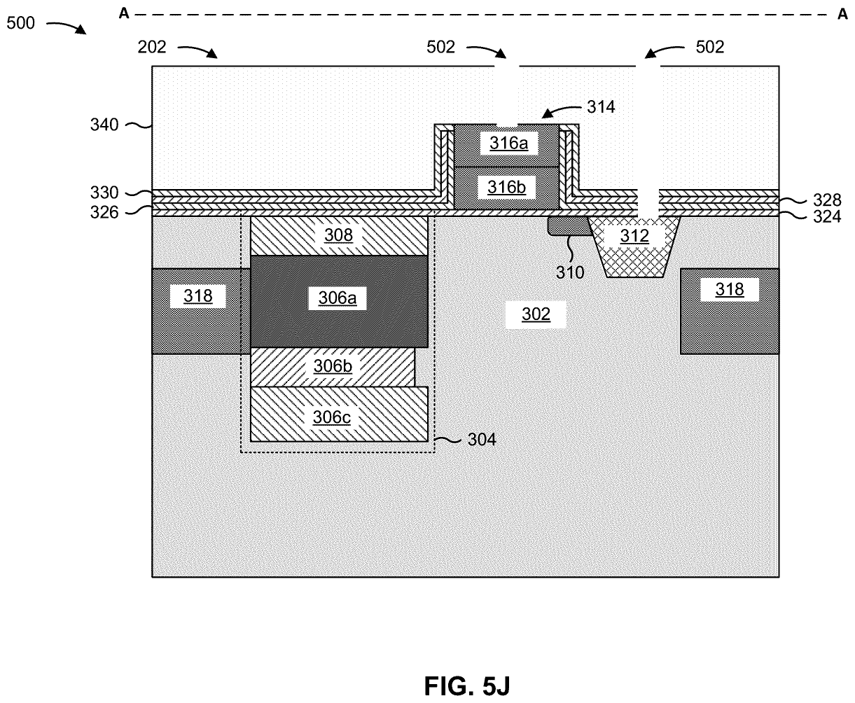

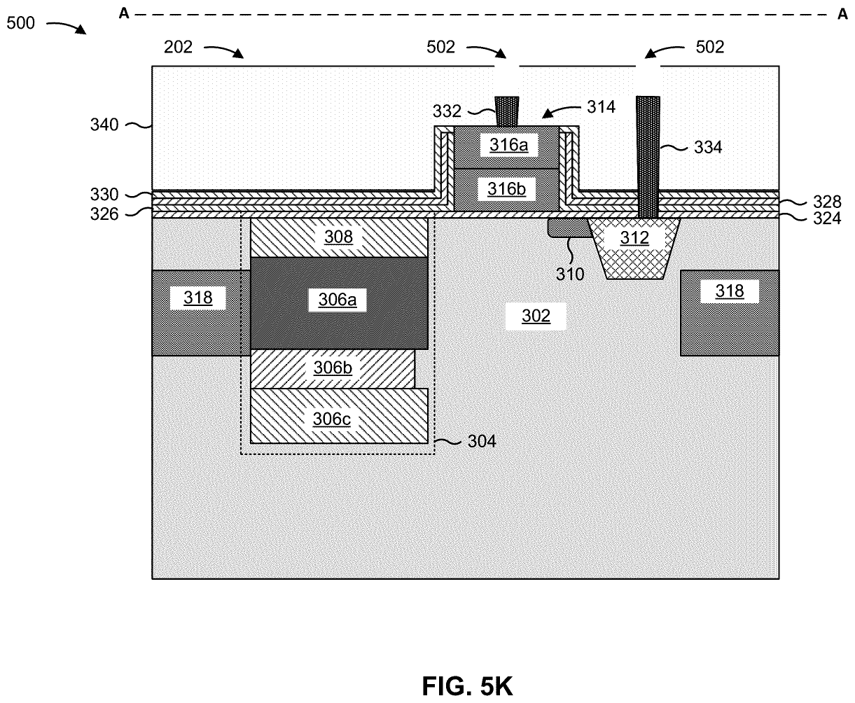

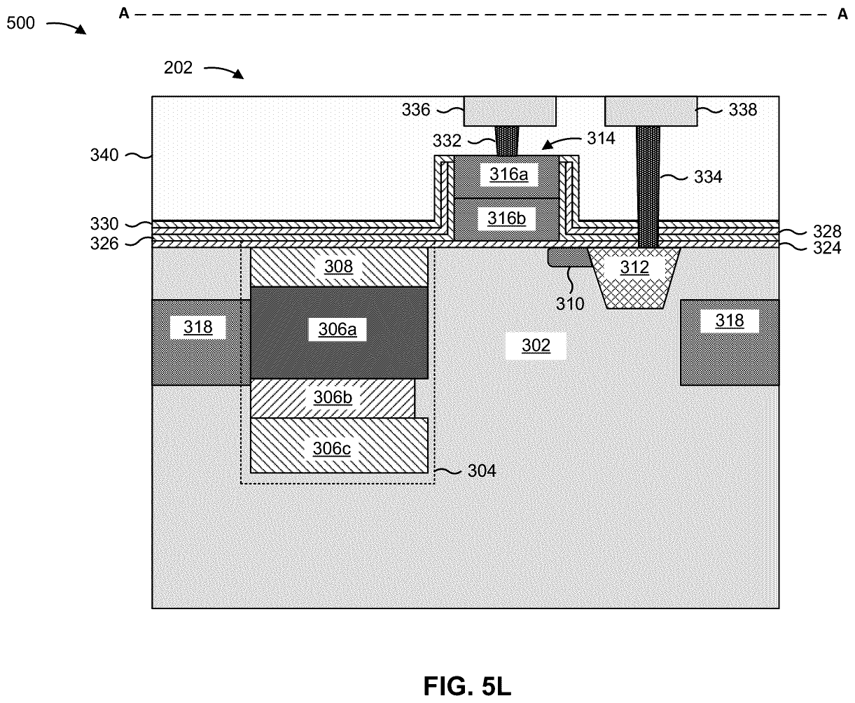

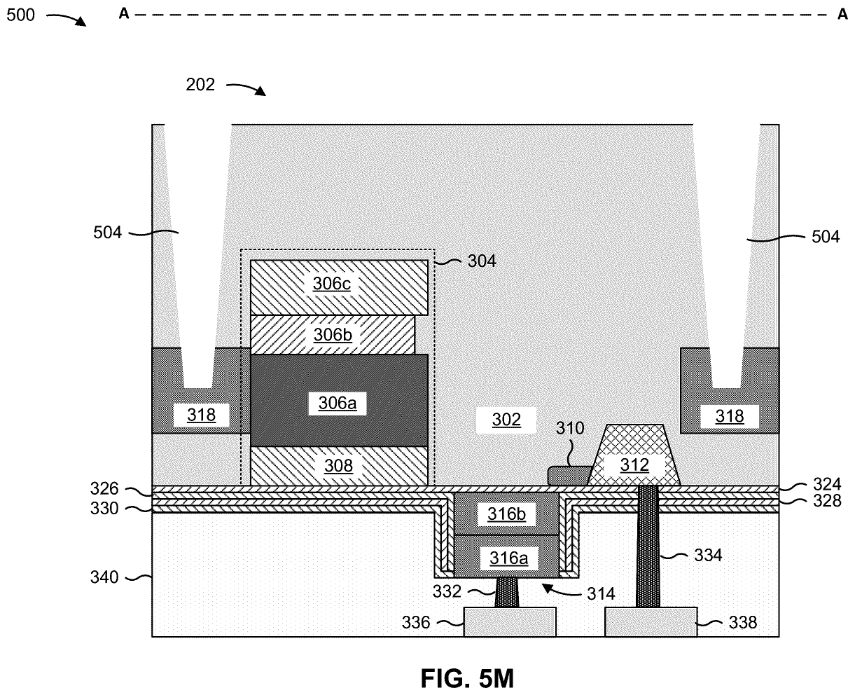

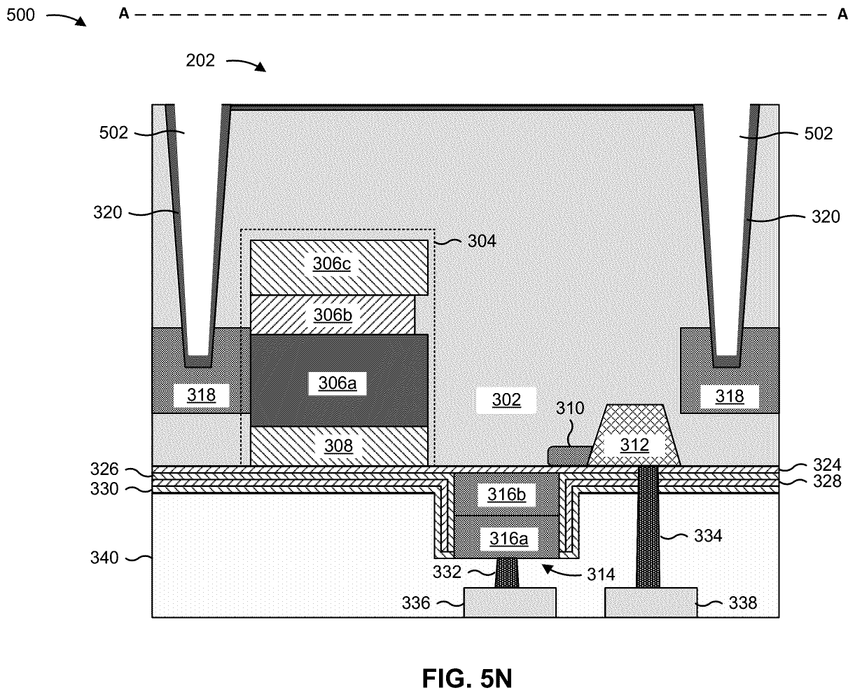

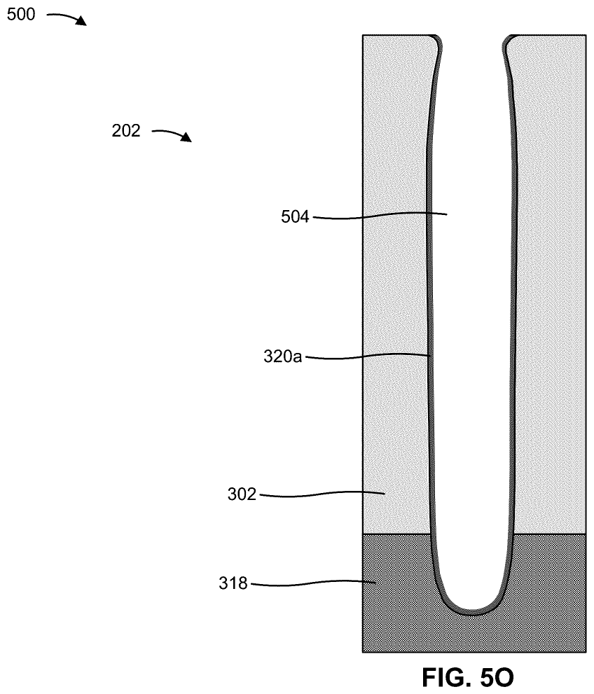

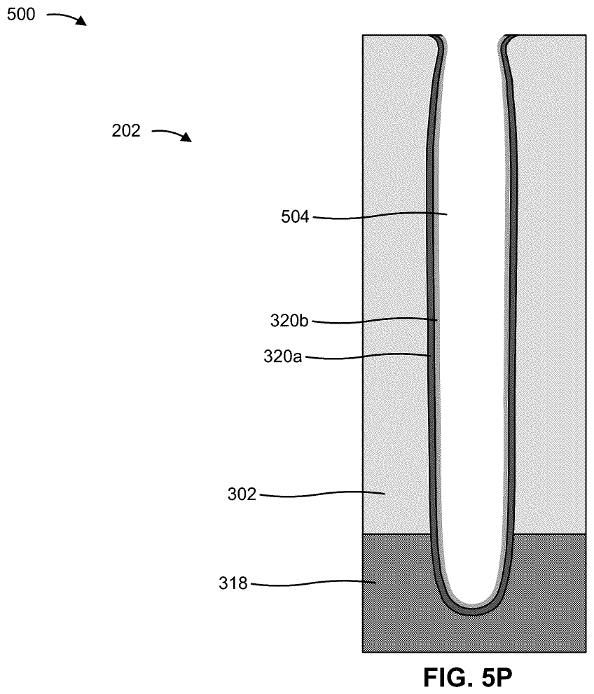

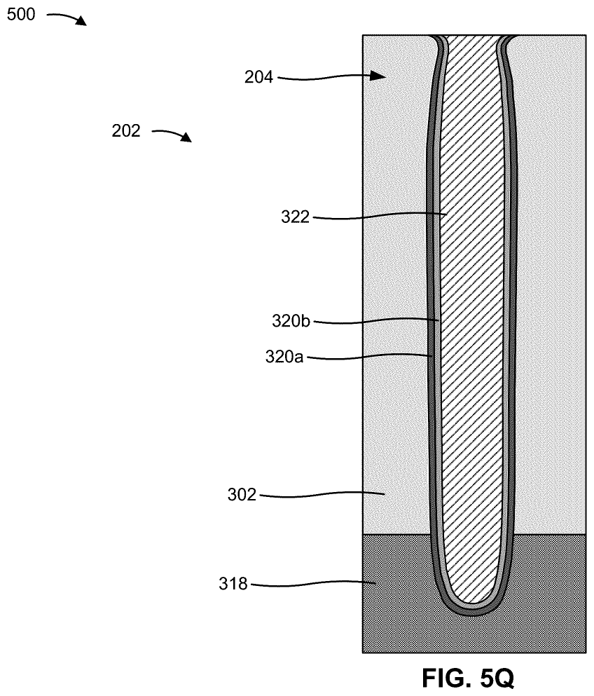

FIGS. 5A-5Q are diagrams of an example implementation 500 described herein. Example implementation 500 may be an example process for forming a pixel sensor 202 described herein, such as the pixel sensor 202 described in connection with FIGS. 3A, 3B, and/or 4A-4D. One or more of FIGS. 5A-5Q are illustrated along the cross-section A-A of the pixel array 200 in FIG. 2. As shown in FIG. 5A, the example process for forming the pixel sensor 300 may be performed in connection with the substrate 302.

As shown in FIG. 5B, the deep p-well region (DPW) 318 may be formed in the substrate 302. For example, the deep p-well region 318 may be formed (e.g., as a circle or ring shape in a top-down view) in the substrate 302 to provide electrical isolation and/or optical isolation for the pixel sensor 202. In some implementations, the ion implantation tool 114 dopes the substrate 302 by ion implantation to form the deep p-well region 318. For example, the ion implantation tool 114 may implant p⁺ ions into a first region of the substrate 302 to form the deep p-well region 318. In some implementations, the ion implantation tool 114 dopes a portion of the substrate 302 above the deep p-well region 318 with p⁺ ions to form a cell p-well region (CPW) above and/or over the deep p-well region 318. In some implementations, the substrate 302 may be doped using another doping technique such as diffusion to form the deep p-well region 318.

As shown in FIGS. 5C and 5D, a plurality of regions of the substrate 302 may be doped to form the photodiode 304. For example, and as illustrated in the example in FIG. 5C, the substrate 302 may be doped to form one or more n-type regions 306b and 306c. As another example, and as illustrated in the example in FIG. 5D, the substrate 302 may be doped to form an n-type region 306a and a p-type region 308.

In some implementations, the ion implantation tool 114 dopes the plurality of regions of the substrate 302 by one or more ion implantation operations. For example, the ion implantation tool 114 may implant p⁺ ions in the substrate 302 to form the p-type region 308, may implant n⁺ ions in the substrate to form the n-type region 306a over and/or on the p-type region 308, may implant n⁺ ions in the substrate 302 to form the n-type region 306b above and/or over the n-type region 306a, and/or may implant n⁺ ions in the substrate 302 to form the n-type region 306c above and/or over the n-type region 306b for a BS-DTI-CIS pixel sensor. As another example, the ion implantation tool 114 may implant n⁺ ions in the substrate 302 to form the n-type region 306c, may implant n⁺ ions in the substrate 302 to form the n-type region 306b above and/or over the n-type region 306c, may implant n⁺ ions in the substrate 302 to form the n-type region 306a above and/or over the n-type region 306b, and may implant p⁺ ions in the substrate 302 to form the p-type region 308 above and/or over the n-type region 306a for a FS-DTI-CIS pixel sensor. The ion implantation tool 114 may form the n-type region 306a, the n-type region 306b, the n-type region 306c, and the p-type region 308 within the perimeter of the deep p-well region 318. In some implementations, the plurality of regions of the substrate 302 may be doped using another doping technique such as diffusion to form the photodiode 304. In some implementations, the n-type region 306a, the n-type region 306b, and/or the n-type region 306c may be doped with different n-type dopant concentrations.

As shown in FIG. 5E, a plurality of regions of the substrate 302 may be doped to form the drain extension region 310 and the drain region 312. In some implementations, the ion implantation tool 114 dopes the plurality of regions of the substrate 302 by one or more ion implantation operations. For example, the ion implantation tool 114 may implant n⁺ ions in the substrate 302 to form the drain region 312, and may implant n⁺ ions in the substrate 302 adjacent to the drain region 312 to form the drain extension region 310. The ion implantation tool 114 may form the drain region 312 and the drain extension region 310 within the perimeter of the deep p-well region 318. In some implementations, the plurality of regions of the substrate 302 may be doped using another doping technique such as diffusion to form the drain region 312 and/or the drain extension region 310. In some implementations, the drain extension region 310 and the drain region 312 may be doped with different n-type dopant concentrations.

As shown in FIG. 5F, the gate dielectric layer 324 may be formed above and/or over the frontside surface of the substrate 302. The deposition tool 102 may deposit the gate dielectric layer 324 using a CVD technique, a PVD technique, an ALD technique, or another type of deposition technique. The planarization tool 110 may planarize the gate dielectric layer 324 after the gate dielectric layer 324 is deposited.

As shown in FIG. 5G, the transfer gate 314 may be formed over and/or on the gate dielectric layer 324. Moreover, the transfer gate 314 may be formed such that the transfer gate 314 is above and between the photodiode 304 and the drain region 312. This enables the transfer gate 314 to selectively form a conductive channel in the substrate 302 between the photodiode 304 and the drain region 312 to control the flow of electrons from the photodiode 304 to the drain region 312.

Forming the transfer gate 314 may include forming the lower transfer gate electrode region 316b over and/or on the gate dielectric layer 324, and forming the n-doped upper transfer gate electrode region 316a over and/or on the lower transfer gate electrode region 316b. The deposition tool 102 may deposit the n-doped upper transfer gate electrode region 316a and/or the lower transfer gate electrode region 316b using a CVD technique, a PVD technique, an ALD technique, an epitaxy technique, or another type of deposition technique; the plating tool 112 may deposit the transfer gate 314 in an electroplating operation; or a combination thereof. In some implementations, the ion implantation tool 114 forms the n-doped upper transfer gate electrode region 316a and/or the lower transfer gate electrode region 316b using one or more ion implantation operations. In some implementations, the planarization tool 110 planarizes the n-doped upper transfer gate electrode region 316a and/or the lower transfer gate electrode region 316b after formation of the n-doped upper transfer gate electrode region 316a and/or the lower transfer gate electrode region 316b.

As shown in FIG. 5H, the sidewall oxide layer 326 may be formed over and/or on the gate dielectric layer 324, on the sidewalls of the n-doped upper transfer gate electrode region 316a, and on the sidewalls of the lower transfer gate electrode region 316b. The deposition tool 102 may deposit the sidewall oxide layer 326 using a CVD technique, a PVD technique, an ALD technique, or another type of deposition technique. In some implementations, the deposition tool 102 deposits the sidewall oxide layer 326 using a conformal deposition technique. In some implementations, the planarization tool 110 planarizes the sidewall oxide layer 326 after the sidewall oxide layer 326 is deposited.

As further shown in FIG. 5H, the remote plasma oxide (RPO) layer 328 may be formed over and/or on the sidewall oxide layer 326, over the sidewalls of the n-doped upper transfer gate electrode region 316a, and over the sidewalls of the lower transfer gate electrode region 316b. The deposition tool 102 may deposit the remote plasma oxide layer 328 using a CVD technique, a PVD technique, an ALD technique, or another type of deposition technique. In some implementations, the deposition tool 102 deposits the remote plasma oxide layer 328 using a conformal deposition technique. In some implementations, the planarization tool 110 planarizes the remote plasma oxide layer 328 after the remote plasma oxide layer 328 is deposited.

As further shown in FIG. 5H, the contact etch stop layer (CESL) 330 may be formed over and/or on the remote plasma oxide layer 328, over the sidewalls of the n-doped upper transfer gate electrode region 316a, and over the sidewalls of the lower transfer gate electrode region 316b. The deposition tool 102 may deposit the contact etch stop layer 330 using a CVD technique, a PVD technique, an ALD technique, or another type of deposition technique. In some implementations, the deposition tool 102 deposits the contact etch stop layer 330 using a conformal deposition technique. In some implementations, the planarization tool 110 planarizes the contact etch stop layer 330 after the contact etch stop layer 330 is deposited.

As shown in FIG. 5I, the dielectric layer(s) 340 may be formed over and/or on the layers 324-330, and over and/or on the transfer gate 314. The deposition tool 102 may deposit the dielectric layer(s) 340 using a CVD technique, a PVD technique, and LAD technique, and/or another deposition technique.

As shown in FIG. 5J, the etch tool 108 forms openings 502 in the dielectric layer(s) 340. The etch tool 108 may form an opening 502 over the transfer gate 314 and through the dielectric layer(s) 340 to the transfer gate 314. The etch tool 108 may also form another opening 502 over the drain region 312 and through the dielectric layer(s) 340 to the drain region 312.

As shown in FIG. 5K, the interconnects 332 and 334 may be formed in the openings 520 in the dielectric layer(s) 340. The interconnect 332 may be formed such that the interconnect 332 is electrically connected with and/or contacts the transfer gate 314 (e.g., the n-doped upper transfer gate electrode region 316a of the transfer gate 314). The interconnect 334 may be formed such that the interconnect 334 is electrically connected with and/or contacts the drain region 312. The deposition tool 102 may deposit the material of the interconnects 332 and 334 using a CVD technique, a PVD technique, an ALD technique, or another type of deposition technique, the plating tool 112 may deposit the material of the interconnects 332 and 334 using an electroplating operation, or a combination thereof. The planarization tool 110 may planarize the interconnects 332 and 334 after the interconnects 332 and 334 are deposited.

As shown in FIG. 5L, the metallization layers 336 and 338 may be formed in the openings 502 in the dielectric layer(s) 340. In particular, the metallization layer 336 may be electrically connected to the transfer gate 314 by the interconnect 332, and the metallization layer 338 may be electrically connected to the drain region 312 by the interconnect 334. The deposition tool 102 may deposit the material of the metallization layers 336 and 338 using a CVD technique, a PVD technique, an ALD technique, or another type of deposition technique, the plating tool 112 may deposit the material of the metallization layers 336 and 338 using an electroplating operation, or a combination thereof. The planarization tool 110 may planarize the metallization layers 336 and 338 after the metallization layers 336 and 338 are deposited.

As shown in FIG. 5M, backside processing of the pixel sensor 202 may be performed. As part of the backside processing, the substrate 302 above the deep p-well region 318 may be etched to form a trench 504 (or another type of recess) in the substrate 302. The trench 504 may be etched into the substrate 302 from the backside surface of the substrate 302, which may be an opposing side of the substrate 302 on which the transfer gate 314 is formed. The trench 504 may be formed such that the trench 504 surrounds the one or more n-type regions 306, the p-type region 308, the drain extension region 310, the drain region 312, and the transfer gate 314. In some implementations, the trench 504 is formed such that the trench 504 partially extends into the deep p-well region 318.

The deposition tool 102 may form a photoresist layer on the substrate 302, the exposure tool 104 may expose the photoresist layer to a radiation source to pattern the photoresist layer, the developer tool 106 may develop and remove portions of the photoresist layer to expose the pattern, and the etch tool 108 may etch portions of the substrate 302 (and, in some cases, portions of the deep p-well region 318) to form the trench 504. In some implementations, a photoresist removal tool removes the remaining portions of the photoresist layer (e.g., using a chemical stripper, a plasma asher, and/or another technique) after the etch tool 108 etches the substrate 302 (and, in some cases, the deep p-well region 318) to form the trench 504.

As shown in FIG. 5N, the trench 504 may be lined with one or more layers 320. The deposition tool 102 may form the one or more layers 320 by conformal deposition such that the one or more layers 320 are formed as thin films that conform to the shape and/or profile of the sidewalls and bottom surface of the trench 504. The one or more layers 320 may include the passivation layer 320a (e.g., an amorphous boron layer), the capping layer 320b, and/or another layer. As further shown in FIG. 5K, the one or more layers 320 (including the passivation layer 320a) may be formed on the backside surface of the substrate 302. In a top-down view, the one or more layers 320 (including the passivation layer 320a) are formed on the backside surface of the substrate 320 within a perimeter of the trench 504.

FIGS. 5O and 5P illustrate details of forming the one or more layers 320. As shown in FIG. 50, the deposition tool 102 may conformally deposit the passivation layer 320a (e.g., a boron layer such as an amorphous boron layer) on sidewalls of the trench 504 and on a bottom surface of the trench 504 such that the passivation layer 320a lines the trench 504. In some implementations, a boron precursor is used to deposit the passivation layer 320a. For example, the deposition tool 102 may use a boron precursor such as diborane (B₂H₆) and/or another boron precursor to deposit the passivation layer 320a. In some implementations, the deposition tool 102 may form the passivation layer 320a to a thickness that is in a range of approximately 1 nanometer to approximately 5 nanometers to enable formation of a continuous film for the passivation layer 320a with a sufficiently low surface roughness and to provide a sufficient amount of negative charge for formation of the depletion region 406a in the substrate 302. However, other values for the range are within the scope of the present disclosure.

The passivation layer 320a may be deposited at a low temperature to minimize and/or prevent formation of boron silicide (BₓSi_{y}) from the boron of the passivation layer 320a and the silicon of the substrate 302, and to promote and/or facilitate formation of a boron-silicon interface (e.g., the interface 404) on the sidewalls and the bottom surface of the trench 504. For example, the deposition tool 102 may form the passivation layer 320a at a temperature that is in a range of approximately 250 degrees Celsius to approximately 450 degrees Celsius. Forming the passivation layer 320a in this example temperature range may provide a sufficient growth rate for the passivation layer 320a and a sufficient absorption coefficient for the passivation layer 320a, while minimizing the likelihood of formation of boron silicide (BₓSi_{y}), and minimizing the likelihood of damage to other layers and/or structures of the pixel sensor 202. However, other values for the range are within the scope of the present disclosure.

In some implementations, the deposition tool 102 uses an LPCVD technique to form the passivation layer 320a. For example, the deposition tool 102 may form the passivation layer 320a at a pressure that is in a range of approximately 10 torr to approximately 500 torr. Forming the passivation layer 320a in this example pressure range may provide a sufficient growth rate for the passivation layer 320a and a sufficient absorption coefficient for the passivation layer 320a, while achieving high film uniformity for the passivation layer 320a. However, other values for the range are within the scope of the present disclosure.

In some implementations, the annealing tool 116 may perform an annealing operation on the passivation layer 320a after the deposition tool 102 forms the passivation layer 320a. In some implementations, the annealing tool 116 and the deposition tool 102 perform a plurality of cyclic deposition and anneal operations. In each cycle, the deposition tool 102 may deposit a portion of the passivation layer 320a and the annealing tool 116 may anneal the portion of the passivation layer 320a. A quantity of the cycles may be performed until a particular thickness for the passivation layer 320a is achieved. The annealing operation may be performed to increase the film quality of the passivation layer 320a (e.g., to remove voids and/or other defects in the passivation layer 320a, to reduce surface roughness of the passivation layer 320a, to increase film uniformity of the passivation layer 320a). The annealing operation may include a laser-based surface annealing operation and/or another type of annealing operation.

As shown in FIG. 5P, the deposition tool 102 may conformally deposit the capping layer 320b (e.g., a silicon layer such as an amorphous silicon layer) over the sidewalls of the trench 504 and over the bottom surface of the trench 504 such that the capping layer 320b is formed on the passivation layer 320a in the trench 504. In some implementations, the deposition tool 102 may form the capping layer 320b to a thickness that is in a range of approximately 1 nanometer to approximately 5 nanometers to enable formation of a continuous film for the capping layer 320b with a sufficiently low surface roughness. However, other values for the range are within the scope of the present disclosure.

The capping layer 320b may be deposited at a low temperature to minimize and/or prevent formation of boron silicide (BₓSi_{y}) from the boron of the passivation layer 320a and the silicon of the capping layer 320b. For example, the deposition tool may form the capping layer 320b at a temperature that is in a range of approximately 250 degrees Celsius to approximately 450 degrees Celsius. Forming the capping layer 320b in this example temperature range may provide a sufficient growth rate for the capping layer 320b and a sufficient absorption coefficient for the capping layer 320b, while minimizing the likelihood of formation of boron silicide (BₓSi_{y}), and minimizing the likelihood of damage to other layers and/or structures of the pixel sensor 202. However, other values for the range are within the scope of the present disclosure.

In some implementations, the deposition tool 102 uses an LPCVD technique to form the capping layer 320b. For example, the deposition tool 102 may form the capping layer 320b at a pressure that is in a range of approximately 10 torr to approximately 500 torr. Forming the capping layer 320b in this example pressure range may provide a sufficient growth rate for the capping layer 320b and a sufficient absorption coefficient for the capping layer 320b, while achieving high film uniformity for the capping layer 320b. However, other values for the range are within the scope of the present disclosure.

As shown in FIG. 5Q, the trench 504 may be filled with an oxide material to form an oxide layer 322 of the DTI structure 204. The deposition tool 102 may form the oxide layer 322 over the passivation layer 320a, over the capping layer 320b, and/or on the capping layer 320b. The deposition tool 102 may deposit the oxide layer 322 using a CVD technique, a PVD technique, an ALD technique, or another type of deposition technique. The planarization tool 110 may planarize the oxide layer 322 after the oxide layer 322 is deposited in the trench 504 such that a top surface of the oxide layer 322 and a backside surface of the substrate 302 are approximately a same height.

In some implementations, a wet cleaning operation may be performed (e.g., by the deposition tool 102 and/or another type of semiconductor processing tool) after formation of the capping layer 320b and prior to formation of the oxide layer 322 in the trench 504. The wet cleaning operation may be performed to clean the trench 504 prior to filling the trench with the oxide material of the oxide layer 322 (e.g., to reduce the likelihood of defect formation in the DTI structure 204). The capping layer 320b may protect the passivation layer 320a from being damaged during the wet cleaning operation.

In some implementations, additional layers and/or structures may be formed for the pixel sensor 202. For example, a p⁺ ion layer 342, an ARC 344, a color filter layer 346, and a micro-lens layer 348 may be formed over the backside side of the substrate 302 (e.g., over the one or more layers 320 on the backside of the substrate 302). The deposition tool 102 may deposit the p⁺ ion layer 342, the ARC 344, the color filter layer 346, and the micro-lens layer 348 using a CVD technique, a PVD technique, an ALD technique, or another type of deposition technique. The p⁺ ion layer 342 may be formed over and/or on the substrate 302. The ARC 344 may be formed over and/or on the p⁺ ion layer 342. The color filter layer 346 may be formed over and/or on the ARC 344. The micro-lens layer 348 may be formed over and/or on the color filter layer 346. In some implementations, the planarization tool 110 planarizes the p⁺ ion layer 342, the ARC 344, and/or the color filter layer 346.

As indicated above, FIGS. 5A-5Q are provided as an example. Other examples may differ from what is described with regard to FIGS. 5A-5Q.

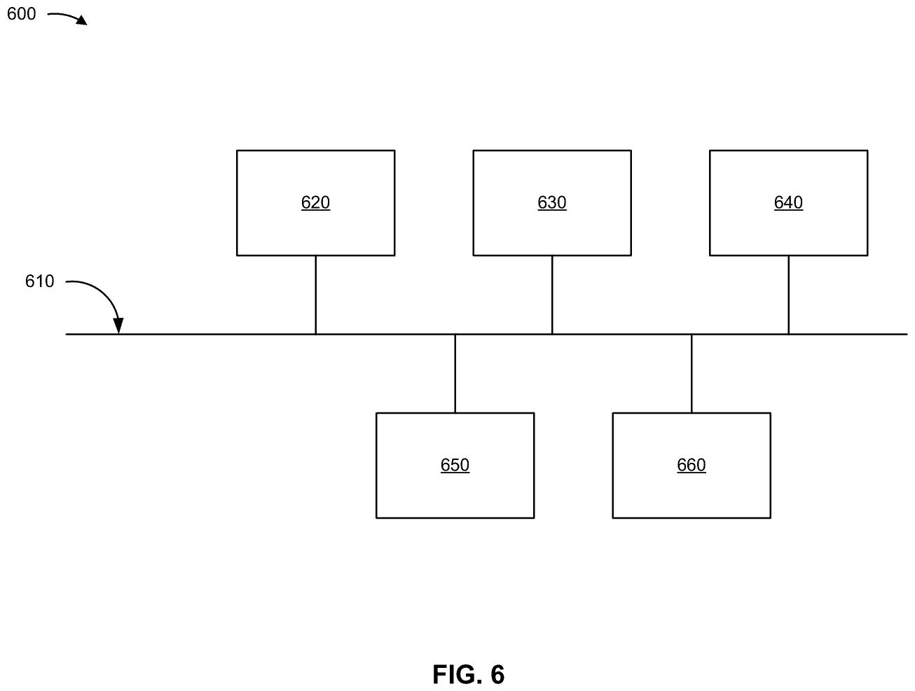

FIG. 6 is a diagram of example components of a device 600. In some implementations, one or more of the semiconductor processing tools 102-116 and/or the wafer/die transport tool 118 may include one or more devices 600 and/or one or more components of device 600. As shown in FIG. 6, device 600 may include a bus 610, a processor 620, a memory 630, an input component 640, an output component 650, and a communication component 660.

Bus 610 includes one or more components that enable wired and/or wireless communication among the components of device 600. Bus 610 may couple together two or more components of FIG. 6, such as via operative coupling, communicative coupling, electronic coupling, and/or electric coupling. Processor 620 includes a central processing unit, a graphics processing unit, a microprocessor, a controller, a microcontroller, a digital signal processor, a field-programmable gate array, an application-specific integrated circuit, and/or another type of processing component. Processor 620 is implemented in hardware, firmware, or a combination of hardware and software. In some implementations, processor 620 includes one or more processors capable of being programmed to perform one or more operations or processes described elsewhere herein.

Memory 630 includes volatile and/or nonvolatile memory. For example, memory 630 may include random access memory (RAM), read only memory (ROM), a hard disk drive, and/or another type of memory (e.g., a flash memory, a magnetic memory, and/or an optical memory). Memory 630 may include internal memory (e.g., RAM, ROM, or a hard disk drive) and/or removable memory (e.g., removable via a universal serial bus connection). Memory 630 may be a non-transitory computer-readable medium. Memory 630 stores information, instructions, and/or software (e.g., one or more software applications) related to the operation of device 600. In some implementations, memory 630 includes one or more memories that are coupled to one or more processors (e.g., processor 620), such as via bus 610.

Input component 640 enables device 600 to receive input, such as user input and/or sensed input. For example, input component 640 may include a touch screen, a keyboard, a keypad, a mouse, a button, a microphone, a switch, a sensor, a global positioning system sensor, an accelerometer, a gyroscope, and/or an actuator. Output component 650 enables device 600 to provide output, such as via a display, a speaker, and/or a light-emitting diode. Communication component 660 enables device 600 to communicate with other devices via a wired connection and/or a wireless connection. For example, communication component 660 may include a receiver, a transmitter, a transceiver, a modem, a network interface card, and/or an antenna.

Device 600 may perform one or more operations or processes described herein. For example, a non-transitory computer-readable medium (e.g., memory 630) may store a set of instructions (e.g., one or more instructions or code) for execution by processor 620. Processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry is used instead of or in combination with the instructions to perform one or more operations or processes described herein. Additionally, or alternatively, processor 620 may be configured to perform one or more operations or processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

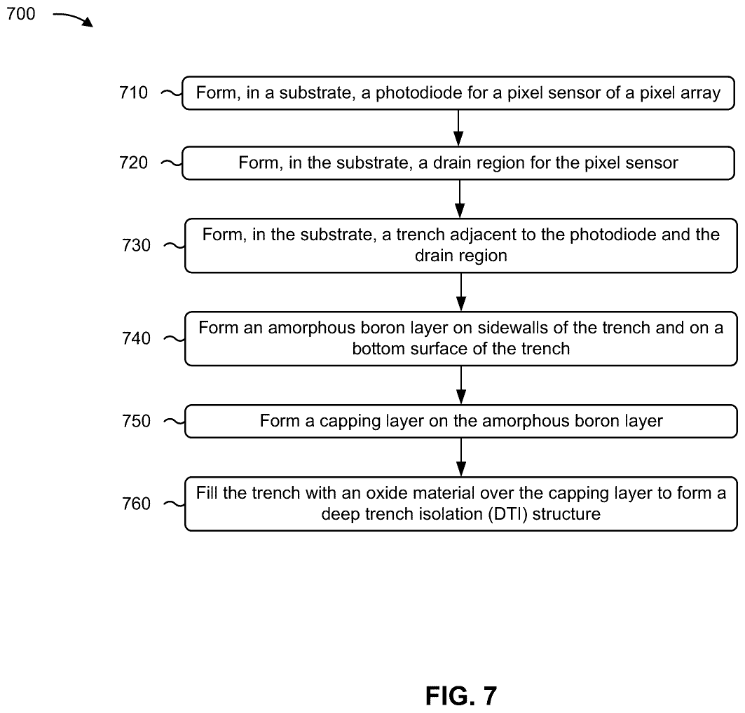

FIG. 7 is a flowchart of an example process 700 associated with forming a pixel sensor. In some implementations, one or more process blocks of FIG. 7 are performed by one or more semiconductor processing tools (e.g., one or more of the semiconductor processing tools 102-116). Additionally, or alternatively, one or more process blocks of FIG. 7 may be performed by one or more components of device 600, such as processor 620, memory 630, input component 640, output component 650, and/or communication component 660.

As shown in FIG. 7, process 700 may include forming, in a substrate, a photodiode for a pixel sensor of a pixel array (block 710). For example, one or more of the semiconductor processing tools 102-116 may form, in a substrate 302, a photodiode 304 for a pixel sensor 202 of a pixel array 200, as described herein.

As further shown in FIG. 7, process 700 may include forming, in the substrate, a drain region for the pixel sensor (block 720). For example, one or more of the semiconductor processing tools 102-116 may form, in the substrate 302, a drain region 312 for the pixel sensor 202, as described herein.

As further shown in FIG. 7, process 700 may include forming, in the substrate, a trench adjacent to the photodiode and the drain region (block 730). For example, one or more of the semiconductor processing tools 102-116 may form, in the substrate 302, a trench 504 adjacent to the photodiode 304 and the drain region 312, as described herein.

As further shown in FIG. 7, process 700 may include forming an amorphous boron layer on sidewalls of the trench and on a bottom surface of the trench (block 740). For example, one or more of the semiconductor processing tools 102-116 may form an amorphous boron layer (e.g., a passivation layer 320a) on sidewalls of the trench 504 and on a bottom surface of the trench 504, as described herein.

As further shown in FIG. 7, process 700 may include forming a capping layer on the amorphous boron layer (block 750). For example, one or more of the semiconductor processing tools 102-116 may form a capping layer 320b on the amorphous boron layer (e.g., the passivation layer 320a), as described herein.

As further shown in FIG. 7, process 700 may include filling the trench with an oxide material over the capping layer to form a DTI structure (block 760). For example, one or more of the semiconductor processing tools 102-116 may fill the trench 504 with an oxide material (e.g., an oxide layer 322) over the capping layer 320b to form a DTI) structure 204, as described herein.

Process 700 may include additional implementations, such as any single implementation or any combination of implementations described below and/or in connection with one or more other processes described elsewhere herein.

In a first implementation, process 700 includes performing a wet cleaning operation in the trench 504 after forming the capping layer 320b and prior to filling the trench with the oxide material (e.g., the oxide layer 322), where the capping layer 320b protects the amorphous boron layer (e.g., the passivation layer 320a) during the wet cleaning operation. In a second implementation, alone or in combination with the first implementation, forming the amorphous boron layer (e.g., the passivation layer 320a) on the sidewalls of the trench 504 and on the bottom surface of the trench 504 results in a charge transfer at an interface 404 between silicon of the substrate 302 and boron of the amorphous boron layer (e.g., the passivation layer 320a). In a third implementation, alone or in combination with one or more of the first and second implementations, the charge transfer results in formation of a depletion region 406a, having a fixed charge density 418, in the substrate 302 adjacent to the interface 404. In a fourth implementation, alone or in combination with one or more of the first through third implementations, forming the amorphous boron layer (e.g., the passivation layer 320a) includes depositing the amorphous boron layer (e.g., the passivation layer 320a) at a temperature that is in a range of approximately 250 degrees Celsius to approximately 450 degrees Celsius.

In a fifth implementation, alone or in combination with one or more of the first through fourth implementations, forming the amorphous boron layer (e.g., the passivation layer 320a) includes depositing the amorphous boron layer (e.g., the passivation layer 320a) at a pressure that is in a range of approximately 10 torr to approximately 500 torr. In a sixth implementation, alone or in combination with one or more of the first through fifth implementations, forming the amorphous boron layer (e.g., the passivation layer 320a) includes depositing the amorphous boron layer (e.g., the passivation layer 320a) using an LPCVD technique and using a diborane (B₂H₆) boron precursor.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

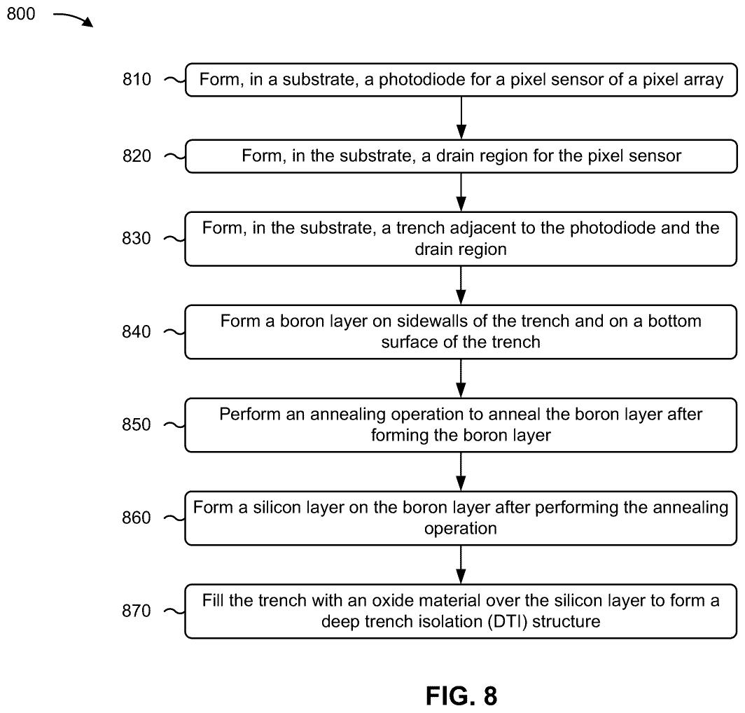

FIG. 8 is a flowchart of an example process 800 associated with forming a pixel sensor. In some implementations, one or more process blocks of FIG. 8 are performed by one or more semiconductor processing tools (e.g., one or more of the semiconductor processing tools 102-116). Additionally, or alternatively, one or more process blocks of FIG. 8 may be performed by one or more components of device 600, such as processor 620, memory 630, input component 640, output component 650, and/or communication component 660.

As shown in FIG. 8, process 800 may include forming, in a substrate, a photodiode for a pixel sensor of a pixel array (block 810). For example, one or more of the semiconductor processing tools 102-116 may form, in a substrate 302, a photodiode 304 for a pixel sensor 202 of a pixel array 200, as described herein.

As further shown in FIG. 8, process 800 may include forming, in the substrate, a drain region for the pixel sensor (block 820). For example, one or more of the semiconductor processing tools 102-116 may form, in the substrate 302, a drain region 312 for the pixel sensor 202, as described herein.

As further shown in FIG. 8, process 800 may include forming, in the substrate, a trench adjacent to the photodiode and the drain region (block 830). For example, one or more of the semiconductor processing tools 102-116 may form, in the substrate 302, a trench 504 adjacent to the photodiode 304 and the drain region 312, as described herein.

As further shown in FIG. 8, process 800 may include forming a boron layer on sidewalls of the trench and on a bottom surface of the trench (block 840). For example, one or more of the semiconductor processing tools 102-116 may form a boron layer (e.g., a passivation layer 320a) on sidewalls of the trench 504 and on a bottom surface of the trench 504, as described herein.

As further shown in FIG. 8, process 800 may include performing an annealing operation to anneal the boron layer after forming the boron layer (block 850). For example, one or more of the semiconductor processing tools 102-116 may perform an annealing operation to anneal the boron layer (e.g., the passivation layer 320a) after forming the boron layer (e.g., the passivation layer 320a), as described herein.

As further shown in FIG. 8, process 800 may include forming a silicon layer on the boron layer after performing the annealing operation (block 860). For example, one or more of the semiconductor processing tools 102-116 may form a silicon layer (e.g., a capping layer 320b) on the boron layer (e.g., the passivation layer 320a) after performing the annealing operation, as described herein.

As further shown in FIG. 8, process 800 may include filling the trench with an oxide material over the silicon layer to form a DTI structure (block 870). For example, one or more of the semiconductor processing tools 102-116 may fill the trench 504 with an oxide material (e.g., an oxide layer 322) over the silicon layer (e.g., the capping layer 320b) to form a DTI structure 204, as described herein.

Process 800 may include additional implementations, such as any single implementation or any combination of implementations described below and/or in connection with one or more other processes described elsewhere herein.

In a first implementation, forming the silicon layer (e.g., the capping layer 320b) includes depositing the silicon layer (e.g., the capping layer 320b) at a temperature that is in a range of approximately 250 degrees Celsius to approximately 450 degrees Celsius. In a second implementation, alone or in combination with the first implementation, forming the silicon layer (e.g., the capping layer 320b) includes depositing the silicon layer (e.g., the capping layer 320b) at a pressure that is in a range of approximately 10 torr to approximately 500 torr. In a third implementation, alone or in combination with one or more of the first and second implementations, performing the annealing operation includes using a laser-based surface annealing technique to perform the annealing operation.

In a fourth implementation, alone or in combination with one or more of the first through third implementations, forming the boron layer (e.g., the passivation layer 320a) includes forming the boron layer (e.g., the passivation layer 320a) to a thickness that is in a range of approximately 1 nanometer to approximately 5 nanometers. In a fifth implementation, alone or in combination with one or more of the first through fourth implementations, forming the silicon layer (e.g., the capping layer 320b) forming the silicon layer (e.g., the capping layer 320b) to a thickness that is in a range of approximately 1 nanometer to approximately 5 nanometers.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

As described herein, a boron layer may be formed as a passivation layer in a recess in which a DTI structure is to be formed. The boron layer results in formation of a boron-silicon interface between the DTI structure and a photodiode of a pixel sensor included in a pixel array. The boron-silicon interface functions as a diode junction, which resists penetration of photons into the DTI structure. This reduces and/or minimizes photon transmission through the DTI structure, which reduces and/or minimizes optical crosstalk between pixel sensors of the pixel array.

As described in greater detail above, some implementations described herein provide a pixel sensor. The pixel sensor includes a silicon substrate. The pixel sensor includes a photodiode in the silicon substrate. The pixel sensor includes a drain region in the silicon substrate. The pixel sensor includes a DTI structure in the silicon substrate, where the DTI structure surrounds the photodiode and the drain region, and where the DTI structure includes a boron layer and an oxide structure over the boron layer.

As described in greater detail above, some implementations described herein provide a method. The method includes forming, in a substrate, a photodiode for a pixel sensor of a pixel array. The method includes forming, in the substrate, a drain region for the pixel sensor. The method includes forming, in the substrate, a trench adjacent to the photodiode and the drain region. The method includes forming an amorphous boron layer on sidewalls of the trench and on a bottom surface of the trench. The method includes forming an amorphous silicon layer on the amorphous boron layer. The method includes filling the trench with an oxide material over the amorphous silicon layer to form a DTI structure.

As described in greater detail above, some implementations described herein provide a method. The method includes forming, in a substrate, a photodiode for a pixel sensor of a pixel array. The method includes forming, in the substrate, a drain region for the pixel sensor. The method includes forming, in the substrate, a trench adjacent to the photodiode and the drain region. The method includes forming a boron layer on sidewalls of the trench and on a bottom surface of the trench. The method includes performing an annealing operation to anneal the boron layer after forming the boron layer. The method includes forming a silicon layer on the boron layer after performing the annealing operation. The method includes filling the trench with an oxide material over the silicon layer to form a DTI structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor, comprising:
a silicon substrate;
a photodiode in the silicon substrate;
a drain region in the silicon substrate; and
a deep trench isolation (DTI) structure in the silicon substrate,
wherein the DTI structure surrounds the photodiode and the drain region, and
wherein the DTI structure comprises:
a boron layer, and
an oxide structure over the boron layer.

2. The pixel sensor of claim 1, wherein the boron layer comprises an amorphous boron material.

3. The pixel sensor of claim 1, wherein the DTI structure further comprises:
a silicon layer between the boron layer and the oxide structure.
wherein the silicon layer comprises an amorphous silicon material.

4. The pixel sensor of claim 3, wherein a thickness of the silicon layer is in a range of approximately 1 nanometer to approximately 5 nanometers.

5. The pixel sensor of claim 3, wherein the silicon substrate comprises a depletion region that is adjacent to an interface between the silicon substrate and the boron layer,
wherein the depletion region is configured to resist photon penetration into the DTI structure.

6. The pixel sensor of claim 5, wherein a negative charge of the boron layer is configured to facilitate formation of the depletion region.

7. The pixel sensor of claim 1, wherein a thickness of the boron layer is in a range of approximately 1 nanometer to approximately 5 nanometers.

8. A method, comprising:
forming, in a substrate, a photodiode for a pixel sensor of a pixel array;
forming, in the substrate, a drain region for the pixel sensor;
forming, in the substrate, a trench adjacent to the photodiode and the drain region;
forming an amorphous boron layer on sidewalls of the trench and on a bottom surface of the trench;
forming a capping layer on the amorphous boron layer; and
filling the trench with an oxide material over the capping layer to form a deep trench isolation (DTI) structure.

9. The method of claim 8, further comprising:
performing a wet cleaning operation in the trench after forming the capping layer and prior to filling the trench with the oxide material,
wherein the capping layer protects the amorphous boron layer during the wet cleaning operation.

10. The method of claim 8, wherein forming the amorphous boron layer on the sidewalls of the trench and on the bottom surface of the trench results in a charge transfer at an interface between silicon of the substrate and boron of the amorphous boron layer.

11. The method of claim 10, wherein the charge transfer results in formation of a depletion region, having a fixed charge density, in the substrate adjacent to the interface.

12. The method of claim 8, wherein forming the amorphous boron layer comprises:
depositing the amorphous boron layer at a temperature that is in a range of approximately 250 degrees Celsius to approximately 450 degrees Celsius.

13. The method of claim 8, wherein forming the amorphous boron layer comprises:
depositing the amorphous boron layer at a pressure that is in a range of approximately 10 torr to approximately 500 torr.

14. The method of claim 8, wherein forming the amorphous boron layer comprises:
depositing the amorphous boron layer using a low pressure chemical vapor deposition (LPCVD) technique and using a diborane (B₂H₆) boron precursor.

15. A method, comprising:
forming, in a substrate, a photodiode for a pixel sensor of a pixel array;
forming, in the substrate, a drain region for the pixel sensor;
forming, in the substrate, a trench adjacent to the photodiode and the drain region;
forming a boron layer on sidewalls of the trench and on a bottom surface of the trench;
performing an annealing operation to anneal the boron layer after forming the boron layer;
forming a silicon layer on the boron layer after performing the annealing operation; and
filling the trench with an oxide material over the silicon layer to form a deep trench isolation (DTI) structure.

16. The method of claim 15, wherein forming the silicon layer comprises:
depositing the silicon layer at a temperature that is in a range of approximately 250 degrees Celsius to approximately 450 degrees Celsius.

17. The method of claim 15, wherein forming the silicon layer comprises:
depositing the silicon layer at a pressure that is in a range of approximately 10 torr to approximately 500 torr.

18. The method of claim 15, wherein performing the annealing operation comprises:
using a laser-based surface annealing technique to perform the annealing operation.

19. The method of claim 15, wherein forming the boron layer comprises:
forming the boron layer to a thickness that is in a range of approximately 1 nanometer to approximately 5 nanometers.

20. The method of claim 15, wherein forming the silicon layer comprises:
forming the silicon layer to a thickness that is in a range of approximately 1 nanometer to approximately 5 nanometers.
